(19) United States
(12) Patent Application Publication
(10) Pub. No.: US 2024/0327661 A1
(43) Pub. Date: Oct. 3, 2024

(54) POLYMER, COPOLYMER, INK, INK CONTAINER, IMAGE FORMING METHOD, IMAGE FORMING DEVICE, AND BACKSHEET FOR SOLAR CELL

(71) Applicant: Shigeyuki Harada, Shizuoka (JP)

(72) Inventor: Shigeyuki Harada, Shizuoka (JP)

(73) Assignee: Ricoh Company, Ltd., Tokyo (JP)

(21) Appl. No.: 18/616,355

(22) Filed: Mar. 26, 2024

(30) Foreign Application Priority Data
Mar. 28, 2023 (JP) 2023-050895

(51) Int. Cl. C09D 11/107; B41J 2/175; C09D 11/037; H01L 31/049

(52) U.S. Cl. CPC C09D 11/107; C09D 11/037; H01L 31/049; B41J 2/17503

(57) ABSTRACT

A polymer contains a structural unit represented by the following Chemical Formula 1

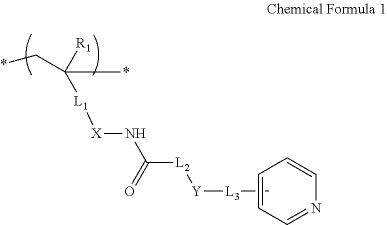

where R₁ represents a hydrogen atom or a methyl group, L₁ represents —COO—, —CONH—, or a simple bonding, X represents a hydrocarbon group with 2 to 10 carbon atoms or a hydrocarbon group including an oxygen atom with 2 to 10 carbon atoms, L₂ represents —O— or —NH—, Y represents a hydrocarbon group with 2 to 12 carbon atoms or a simple bonding, and L₃ represents —OCO—, —O—, —(CH₂)ₙ—, or —OCO—(CH₂)ₙ—, where n represents an integer of from 1 to 3.

### CROSS-REFERENCE TO RELATED APPLICATIONS

This patent application is based on and claims priority pursuant to 35 U.S.C. § 119 to Japanese Patent Application No. 2023-050895, filed on Mar. 28, 2023, in the Japan Patent Office, the entire disclosure of which is hereby incorporated by reference herein.

### BACKGROUND

### Technical Field

The present disclosure relates to a polymer, a copolymer, an ink, an ink container, an image forming method, an image forming device, and a backsheet for solar cell.

### Description of the Related Art

Inkjet printers are widely used as printers for printing on paper media. For other media such as transparent or colored plastic film and colored fabrics, white ink is required to conceal the background in addition to black ink, yellow ink, magenta ink, and cyan ink.

One such white ink pigment highly capable of concealing the background is titanium oxide, rutile form, with a high refractive index.

### SUMMARY

According to embodiments of the present disclosure, a polymer is provided that contains a structural unit represented by the following Chemical Formula 1

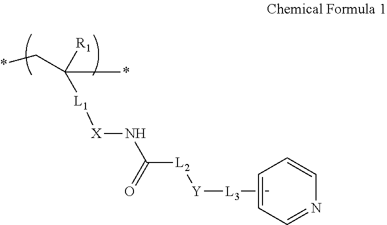

where R₁ represents a hydrogen atom or a methyl group, L₁ represents —COO—, —CONH—, or a simple bonding, X represents a hydrocarbon group with 2 to 10 carbon atoms or a hydrocarbon group including an oxygen atom with 2 to 10 carbon atoms, L₂ represents —O— or —NH—, Y represents a hydrocarbon group with 2 to 12 carbon atoms or a simple bonding, and L₃ represents —OCO—, —O—, —(CH₂)ₙ—, or —OCO—(CH₂)ₙ—, where n represents an integer of from 1 to 3.

As another aspect of embodiments of the present disclosure, a copolymer is provided that contains a structural unit represented by the following Chemical Formula 1 and a structural unit represented by Chemical Formula 2,

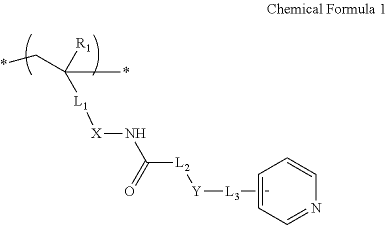

where R₁ represents a hydrogen atom or a methyl group, L₁ represents —COO—, —CONH—, or a simple bonding, X represents a hydrocarbon group with 2 to 10 carbon atoms or a hydrocarbon group including an oxygen atom with 2 to 10 carbon atoms, L₂ represents —O— or —NH—, Y represents a hydrocarbon group with 2 to 12 carbon atoms or a simple bonding, and L₃ represents —OCO—, —O—, —(CH₂)ₙ—, or —OCO—(CH₂)ₙ—, where n represents an integer of from 1 to 3.

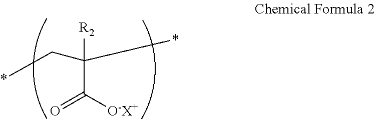

where R₂ represents a hydrogen atom or a methyl group and X⁺ represents a proton or an organic or inorganic cation.

As another aspect of embodiments of the present disclosure, an ink is provided that contains water, a coloring material, and either a polymer or a copolymer, the polymer containing a structural unit represented by the following Chemical Formula 1,

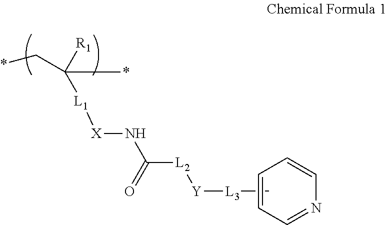

where R₁ represents a hydrogen atom or a methyl group, L₁ represents —COO—, —CONH—, or a simple bonding, X represents a hydrocarbon group with 2 to 10 carbon atoms or a hydrocarbon group including an oxygen atom with 2 to 10 carbon atoms, L₂ represents —O— or —NH—, Y represents a hydrocarbon group with 2 to 12 carbon atoms or a simple bonding, and L₃ represents —OCO—, —O—, —(CH₂)ₙ—, or —OCO—(CH₂)ₙ—, where n represents an integer of from 1 to 3 and the copolymer containing a structural unit represented by Chemical Formula 1 and a structural unit represented by Chemical Formula 2,

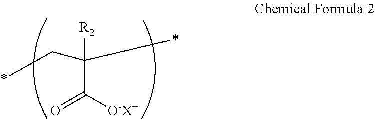

where R₂ represents a hydrogen atom or a methyl group and X⁺ represents a proton or an organic or inorganic cation.

As another aspect of embodiments of the present disclosure, an ink container is provided that contains the ink mentioned above.

As another aspect of embodiments of the present disclosure, an image forming method is provided that includes discharging the ink mentioned above 3 to a printing medium to form an image thereon.

As another aspect of embodiments of the present disclosure, an image forming device is provided that includes the ink container mentioned above and a discharging device to discharge the ink to a printing medium.

As another aspect of embodiments of the present disclosure, a backsheet for solar cell is provided that includes a protection layer including a coated film formed of the ink mentioned above.

### BRIEF DESCRIPTION OF THE SEVERAL VIEWS OF THE DRAWINGS

A more complete appreciation of the disclosure and many of the attendant advantages and features thereof can be readily obtained and understood from the following detailed description with reference to the accompanying drawings, wherein:

FIG. 1 is a schematic diagram illustrating an example of the image forming device; and

FIG. 2 is a schematic diagram illustrating an example of a process cartridge using an embodiment of the present invention.

The accompanying drawings are intended to depict example embodiments of the present invention and should not be interpreted to limit the scope thereof. The accompanying drawings are not to be considered as drawn to scale unless explicitly noted.

Also, identical or similar reference numerals designate identical or similar components throughout the several views.

### DESCRIPTION OF THE EMBODIMENTS

The terminology used herein is for the purpose of describing particular embodiments only and is not intended to be limiting of the present invention. As used herein, the singular forms “a,” “an,” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Embodiments of the present invention are described in detail below with reference to accompanying drawings. In describing embodiments illustrated in the drawings, specific terminology is employed for the sake of clarity. However, the disclosure of this patent specification is not intended to be limited to the specific terminology so selected, and it is to be understood that each specific element includes all technical equivalents that have a similar function, operate in a similar manner, and achieve a similar result.

For the sake of simplicity, the same reference number will be given to identical constituent elements such as parts and materials having the same functions and redundant descriptions thereof omitted unless otherwise stated.

According to the present disclosure, a polymer is provided with which a coloring material dispersion with an excellent storage stability, an ink with an excellent storage stability and re-dispersibility, and an excellent weather-resistant backsheet for solar cell can be manufactured.

A carboxylic group-containing A-B block copolymer, composed of methacrylate containing an aliphatic cyclic alkyl group with at least 6 carbon atoms and methacrylic acid, has been proposed as a dispersant of titanium oxide in Japanese Unexamined Patent Application Publication No. 2014-40553 (Japanese Patent No. 5863600) Titanium oxide, in its rutile form, used in typical white ink with high concealing properties, has a specific gravity of 4.17 g/mL and is known to settle over time in the ink, eventually leading to separation. The white ink in a dispersed state, even when aggregated, can be used without a problem as long as it can return to the dispersion state through agitation or shaking. However, in reality, the white ink becomes unusable when titanium dioxide sedimented in the lower layer of the ink aggregates, preventing re-dispersion of the ink and causing it to aggregate instead. Furthermore, this failure to return to the dispersed state leads to issues such as increased ink viscosity, decreased white coverage, and defective discharging.

The typical dispersant disclosed in Japanese Unexamined Patent Application Publication No. 2014-40553 mentioned above needs a further enhancement on the storage stability of ink and re-dispersibility of a coloring material.

The inventors of the present invention have found through a keen investigation that a coloring material dispersion with an excellent storage stability and an ink with an excellent storage stability and re-dispersibility are obtained from a polymer with a structural unit represented by Chemical Formula 1 or a copolymer with the structural unit represented by Chemical Formula 1 and a structural unit represented by Chemical Formula 2.

Furthermore, the inventors have found that a film containing a coloring material such as titanium oxide, uniformly dispersed without aggregation, can be obtained from ink containing water, a coloring material, and either a polymer or a copolymer. The polymer contains a structural unit represented by Chemical Formula 1, and the copolymer contains a structural unit represented by Chemical Formula 1 and a structural unit represented by Chemical Formula 2. Additionally, the inventors have also found that applying the obtained film as a protection layer to a backsheet of a solar cell results in one with excellent weather resistance.

Embodiments of the present disclosure are described below.

### Polymer

The polymer related to the present disclosure has a structural unit represented by Chemical Formula 1 and optionally other polymerizable monomers.

In this specification, the structural unit represented by Chemical Formula 1 is also referred to as “first monomer”.

In this specification, the polymer having the structural unit represented by Chemical Formula 1 is also referred to as “polymer”. In the specification, the polymer of the present disclosure containing other polymerizable monomers described later is also described as “polymer” for convenience.

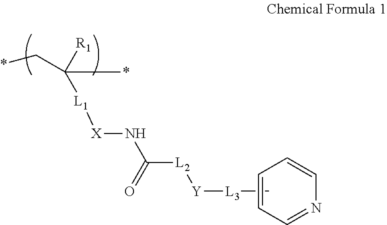

In Chemical Formula 1, R₁ represents a hydrogen atom or a methyl group, L₁ represents —COO—, —CONH—, or a simple bonding, X represents a hydrocarbon group with 2 to 10 carbon atoms or a hydrocarbon group including an oxygen atom with 2 to 10 carbon atoms, L₂ represents —O— or —NH—, Y represents a hydrocarbon group with 2 to 12 carbon atoms or a simple bonding, and L₃ represents —OCO—, —O—, —(CH₂)ₙ—, or —OCO—(CH₂)ₙ—, where n represents an integer of from 1 to 3.

The pyridyl group present at a terminal of the polymer with the structural unit represented by Chemical Formula 1, acting as a Lewis base, enhances the polymer's adsorption onto the surface of a particle, such as titanium oxide, alumina-treated titanium oxide, and barium sulfate.

The pyridyl group in the structural unit represented by Chemical Formula 1, which is located away from the main chain of the polymer, makes it less vulnerable to inhibition of dye adsorption by other components (such as structural units represented by Chemical Formula 2) involved in (co)polymerization.

Furthermore, —NHCO—NH— or —NH—COO— group linked to the linking groups X and Y in Chemical Formula 1 imparts water solubility to the polymer. This mechanism enables the improvement of dispersion stability of coloring material and the formulation of ink with high storage stability. In other words, a coloring material dispersion containing a coloring material dispersed in water, which is described later, prepared with the polymer of the present disclosure achieves highly dispersibility and long-term stability.

The weight average molecular weight Mw of the polymer of the present disclosure is preferably 5,000 to 50,000 from the viewpoints of storage stability of coloring material dispersions and ink, as well as redispersibility of ink, with a preference for between 15,000 and 40,000.

There is no particular limitation on the method of measuring the weight average molecular weight Mw of the polymer. It can be measured by the following method, for example.

### Example of Method of Manufacturing Weight Average Molecular Weight Mw

The weight average molecular weight of the polymer was measured by gel permeation chromatography (GPC) under the following devices and conditions:
Device: GPC-8320 GPC (available from TOSOH CORPORATION)
Column: TSK G2000 HXL and G4000 HXL (available from TOSOH CORPORATION)
Temperature: 40 degrees C.
Solvent: Tetrahydrofuran (TIF)
Rate of flow: 0.6 mL/min.

One milliliter of a polymer with a concentration of 0.5 percent by mass was infused into the device, and the weight average molecular weight Mw of the polymer was calculated using the molecular weight calibration curve created based on monodisperse polystyrene standard samples from the molecular weight distribution of the polymer measured under the conditions specified above.

The method of preparing the structural unit represented by Chemical Formula 1 is not particularly limited and can be suitably selected to suit to a particular application. One such method is as follows.

### Example of Preparing Structural Unit Represented by Chemical Formula 1

Pyridylcarboxylic Acid A-1 is allowed to conduct condensation reaction with an excess amount of diol to obtain Pyridinecarboxylic Acid Hydroxyalkyl Ester A-2.

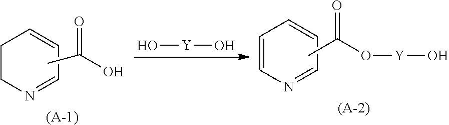

Subsequently, Isocyanate Compound A-3 is allowed to react with a group such as an acrylic group and Pyridinecarboxylic Acid Hydroxyalkyl Ester A-2 to obtain Monomer A-4.

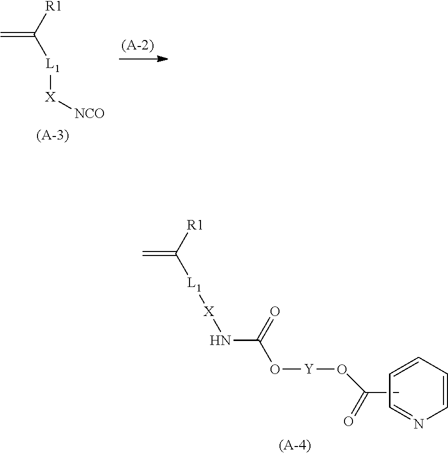

Monomer A-4 is polymerized in the presence of a radical polymerization initiator to obtain Polymer A-5.

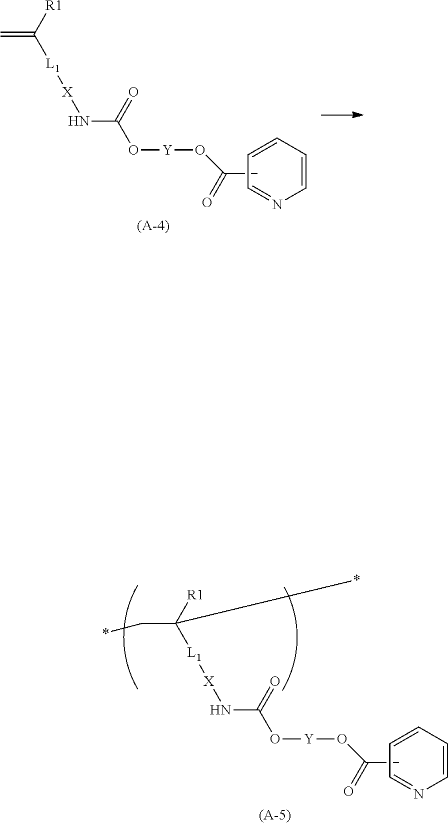

### Copolymer

The copolymer of the present disclosure has the structural unit represented by Chemical Formula 1, the structural unit represented by Chemical Formula 2, and may optionally include other polymerizable monomers.

In this specification, the structural unit represented by Chemical Formula 2 is also referred to as a “second monomer”.

In this specification, the “copolymer having the structural unit represented by Chemical Formula 1 and the structural unit represented by Chemical Formula 2” is also referred to as a “copolymer”.

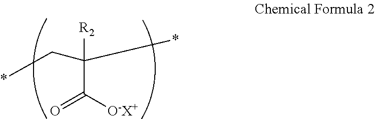

In Chemical Formula 2, R₂ represents a hydrogen atom or a methyl group and X represents a proton or an organic or inorganic cation.

The protons or cations in Chemical Formula 2 induces electrostatic repulsion forces between copolymer molecules, thereby hindering the aggregation of coloring materials. Consequently, even if the coloring material precipitates in the ink, it can be easily redispersed, resulting in an ink with high redispersibility. In other words, a coloring material dispersion containing a coloring material dispersed in water, which is described later, prepared with the polymer of the present disclosure can enhance dispersibility, re-dispersibility, and storage stability.

The proton or cation is not particularly limited and can be suitably selected to suit to a particular application.

Specific examples of the cation include, but are not limited to, sodium ion, potassium ion, lithium ion, tetramethyl ammonium ion, tetraethyl ammonium ion, tetrapropyl ammonium ion, tetrabutyl ammonium ion, tetrapentyl ammonium ion, tetrahexyl ammonium ion, triethylmethyl ammonium ion, tributylmethyl ammonium ion, trioctylmethyl ammonium ion, 2-hydroxyethyl trimethyl ammonium ion, tris(2-hydroxyethyl)methyl ammonium ion, propyltrimethyl ammonium ion, hexyltrimethyl ammonium ion, octyltrimethyl ammonium ion, nonyltrimethyl ammonium ion, decyltrimethyl ammonium ion, dodecyltrimerthyl ammonium ion, tetradecyltrimethyl ammonium ion, hexadecyl trimethyl ammonium ion, octadecyl trimethyl ammonium ion, didodecyl dimethyl ammonium ion, ditetradecyl dimethyl ammonium ion, dihexyadecyl dimethyl ammonium ion, dioctadecyl dimethyl ammonium ion, ethylhexadecyl dimethyl ammonium ion, ammonium ion, dimethyl ammonium ion, trimethyl ammonium ion, monoethyl ammonium ion, diethyl ammonium ion, triethyl ammonium ion, monoethanol ammonium ion, diethanol ammonium ion, triethanol ammonium ion, methyl ethanol ammonium ion, methyldiethanol ammonium ion, dimethylethanol ammonium ion, monopropanol ammonium ion, dipropanol ammonium ion, tripropanol ammonium ion, isopropanol ammonium ion, morpholinium ion, N-methyl morpholinium ion, N-methyl-2-pyrolidonium ion, and 2-pyrolidonium ion.

The weight average molecular weight Mw of the copolymer of the present disclosure is preferably 5,000 to 50,000 from the viewpoints of storage stability of coloring material dispersions and ink, as well as redispersibility of ink, with a preference for between 15,000 and 40,000.

There are no specific limitations on the method for measuring the weight-average molecular weight Mw of the copolymer. Its weight average molecular weight Mw can be measured in, for example, the same manner as described in Example of Method of Measuring Weight Average Molecular Weight Mw.

The structure of the copolymer of the present disclosure is not particularly limited and can be suitably selected to suit to a particular application. Examples include, but are not limited to, a random copolymer, a graft copolymer, and a block copolymer.

There are no specific limitations on the method of synthesizing the copolymer of the present disclosure, and they can be suitably selected to suit to a particular application. One method of synthesizing Copolymer A-7 is to copolymerize Monomer A-4, obtained in Example of Preparing Structural Unit Represented by Chemical Formula 1, with Methacrylic Acid A-6 in the presence of a radical polymerization initiator.

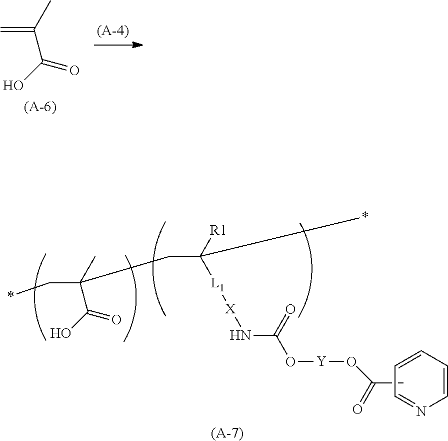

### Other Polymerizable Compound

The polymer or copolymer of the present disclosure has a structural unit represented by Chemical Formula 1, a structure unit represented by Chemical Formula 2, and other optional polymerizable monomers.

Such other polymerizable monomers are not particularly limited and can be suitably selected to suit to a particular application. Examples include, but are not limited to, hydrophobic polymerizable monomers, hydrophillic polymerizable monomers, and polymerizable surfactants.

In the specification, the “other optional polymerizable monomer” is also referred to as “third monomer”.

### Hydrophobic Polymerizable Monomer

The hydrophobic polymerizable monomers are not particularly limited and they can be suitably selected to suit to a particular application.

Specific examples include, but are not limited to, unsaturated ethylene monomers having aromatic ring such as α-methyl styrene, 4-t-butyl styrene, and 4-chloromethyl styrene; (meth)acrlic acid alkyl such as methyl (meth)acrylate, ethyl(meth)acrylate, n-butyl(meth)acrylate, dimethyl maleate, dimethyl itaconate, dimethyl fumarate, lauryl(meth)acrylate (C12), tridecyl(meth)acrylate (C13), tetradecyl(meth)acrylate (C14), pentadecyl(meth)acrylate (C15), hexadecyl(meth)acrylate (C16), heptadecyl(meth)acrylate (C17), nonadecyl(meth)acrylate (C19), eicosyl(meth)acrylate (C20), heneicosyl(meth)acrylate (C21), and docosyl(meth)acrylate (C22); and unsaturated ethylene monomers having an alkyl group such as 1-heptene, 3,3-dimethyl-1-pentene, 4,4-dimethyl-1-pentene, 3-methyl-1-hexene, 4-methyl-1-hexene, 5-methyl-1-hexene, 1-octene, 3,3-dimethyl-1-hexene, 3,4-dimethyl-1-hexene, 4,4-dimethyl-1-hexene, 1-nonene, 3,5,5-trimethyl-1-hexene, 1-decene, 1-undecene, 1-dodecene, 1-tridecene, 1-tetracene, 1-pentadecene, 1-hexadecene, 1-heptadecene, 1-octadecene, 1-nonadecene, 1-eicocene, and 1-dococene. These can be used alone or in combination.

### Hydrophillic Polymerizable Monomer

The hydrophillic polymerizable monomers are not particularly limited and they can be suitably selected to suit to a particular application.

Specific examples include, but are not limited to, anionic unsaturated ethylene monomers such as maleic acid or its salts, monomethyl maleate, itaconic acid, monomethyl itaconate, fumaric acid, 4-styrene sulfonic acid, 2-acrylic amide-2-methyl propane sulfonic acid, or anionic unsaturated ethylene monomers such as unsaturated ethylenic monomers with phosphoric acid, phosphonic acid, alendronic acid, or etidronic acid; and nonionic unsaturated ethylene monomers such as 2-hydroxyethyl (meth)acrylic acid, diethylene glycol mono(meth)acrylate, triethylene glycol mono(meth)acrylate, tetraethylene glycol mono(meth)acrylate, polyethylene glycol mono(meth)acrylate, (meth)acrylamide, N-methylol(meth)acrylamide, N-vinyl formamide, N-vinylacetoamide, N-vinylpyrrolidone, acrylamide, N,N-dimethyl acrylamide, N-t-butyl acrylamide, N-octyl acrylamide, and N-t-octyl acrylamide.

The proportion of the hydrophobic polymerizable monomer and the hydrophillic polymerizable monomer is not particularly limited and can be suitably selected to suit to a particular application. It is possibly from 5 to 100 percent by mass to the sum of the monomers forming a polymer having a structural unit represented by Chemical Formula 1 or the monomers forming a copolymer having a structural unit represented by Chemical Formula 1 and a structural unit represented by Chemical Formula 2.

### Polymerizable Surfactant

The polymerizable surfactant mentioned above contains at least one radically-polymerizable unsaturated double bond group in its molecule. Examples include, but are not limited to, an anionic surfactant and a nonionic surfactant.

### Anionic Surfactant

The anionic surfactant is not particularly limited and can be suitably selected to suit to a particular application.

Examples include, but are not limited to, a hydrocarbon compound having a sulfate group such as ammonium sulfate group (—SO₃—NH₄⁺) and an allyl group (—CH₂—CH═CH₂), a hydrocarbon compound having a sulfate group such as ammonium sulfate group (—SO₃—NH₄⁺) and a methacylic group [(—CO—C(CH₃)═CH₂], and an aromatic hydrocarbon compound having a sulfate group such as an ammonium sulfate group (—SO₃—NH₄⁺) and a 1-propenyl group (—CH═CH₂CH₃).

Specific examples of the anionic surfactant include, but are not limited to, ELEMINOL JS-20 and RS-300 (both available from Sanyo Chemical Industries, Ltd.) and Aqualon KH-10, Aqualon KH-1025, Aqualon KH-05, Aqualon HS-10, Aqualon HS-1025, Aqualon BC-0515, Aqualon BC-10, Aqualon BC-1025, Aqualon BC-20, and Aqualon BC-2020 (all available from DKS Co. Ltd.).

### Nonionic Surfactant

The nonionic surfactant is not particularly limited and can be suitably selected to suit to a particular application. Examples include, but are not limited to, a hydrocarbon compound or an aromatic hydrocarbon compound having 1-propenyl group (—CH═CH₂CH₃) and a polyoxyethylene group [—(C₂H₄O)ₙ—H]. “n” in the polyoxyethyle group refers to an integer of 2 or greater.

Specific examples of the nonionic surfactant include, but are not limited to, Aqualon RN-20, Aqualon RN-2025, Aqualon RN-30, and Aqualon RN-50 (all available from DKS Co. Ltd.) and LATEMUL PD-104, LATEMUL PD-420, LATEMUL PD-430, and LATEMUL PD-450 (all available from Kao Corporation).

The proportion of the polymerizable surfactant is not particularly limited and can be suitably selected to suit to a particular application. For example, it is possibly from 0.1 to 10 percent by mass to the sum of the monomers forming a polymer having a structural unit represented by Chemical Formula 1 or the monomers forming a copolymer having a structural unit represented by Chemical Formula 1 and a structural unit represented by Chemical Formula 2.

A radical polymerization initiator may be used in the process of forming the polymer or the copolymer of the present disclosure.

The radical polymerization initiator is not particularly limited and can be suitably selected to suit to a particular application. Specific examples include, but are not limited to, peroxyketal, hydroperoxide, dialkyl peroxide, diacyl peroxide, peroxydicarbonate, peroxyester, cyano-based azobisisobutyronitrile, azobis (2-methylbutyronitrile), azobis (2,2′-isovaleronitrile), and non-cyano-based dimethyl-2,2′-azobisisobutyrate. Of these, organic peroxides and azo-based compounds are preferable and azo-based compounds are more preferable because their molecular weight can be easily adjusted and they are decomposed at low temperatures.

The proportion of the radical polymerization initiator is not particularly limited and can be suitably selected to suit to a particular application. It is preferably from 1 to 10 percent by mass to the sum of polymerizable monomers.

The polymerizable monomer includes all of the monomers forming a polymer having a structural unit represented by Chemical Formula 1, the monomers forming a copolymer having a structural unit represented by Chemical Formula 2, and all the other polymerizable monomers.

To adjust the molecular weight of the polymer and the copolymer of the present disclosure, a chain transfer agent is optionally added.

The chain transfer agent is not particularly limited and can be suitably selected to suit to a particular application.

Specific examples thereof include, but are not limited to, mercapto acetate, mercapto propionate, 2-propane thiol, 2-meracapto ethanol, thiophenol, dodecyl mercaptane, 1-dodecane thiol, and thioglycerol.

The polymerization temperature of the polymer and the copolymer of the present disclosure is not particularly limited and can be suitably selected to a particular application. It is preferably from 50 to 150 degrees C. and more preferably from 60 to 100 degrees C.

The polymerization time for forming the polymer and the copolymer of the present disclosure is not particularly limited and can be suitably selected to a particular application. It is preferably from 3 to 48 hours.

There are no particular restrictions on the content of the structural unit represented by Chemical Formula 1 in the polymer or copolymer, and they can be appropriately selected according to the purpose. It is preferable that the content of the structural unit represented by Chemical Formula 1 in the polymer or copolymer is 75 to 95 mass percent or less of the total amount of the polymer or copolymer, more preferably from 80 to 90 percent by mass.

The preferred range mentioned above of the content of the structural unit represented by Chemical Formula 1 leads to achieving improved storage stability of the ink.

The content of the structural unit represented by Chemical Formula 2 in the polymer or copolymer is not particularly limited and it can be suitably selected to suit to a particular application. It is preferable that the content of the structural unit represented by Chemical Formula 2 in the polymer or copolymer be between 5.0 and 35.0 percent by mass of its total amount, with a more preferred range of from 15.0 to 25.0 percent by mass.

The preferred range mentioned above of the content of the structural unit represented by Chemical Formula 2 results in improved solubility to water and dispersion stability therein.

The content of the first monomer and the third monomer in the polymer of the present disclosure, as well as the content of the first monomer, the second monomer, and the third monomer in the copolymer of the present disclosure, can be determined by combining ¹H-NMR, ¹³C-NMR, GC-MS, LC-MS, and LC-MS/MS measurements.

The content of the second monomer in the copolymer of the present disclosure can be quantified by a method of neutralization titration including adding a solution containing a certain amount of the copolymer dropwise to a solution containing the titration indicator such as phenolphthalein.

### Ink

The ink of the present disclosure contains a polymer with the structural unit represented by Chemical Formula 1 or a copolymer with the structural unit represented by Chemical Formula 1 and the structural unit represented by Chemical Formula 2, and other optional components.

The polymer with the structural unit represented by Chemical Formula 1 or the structural unit represented by Chemical Formula 1 and the copolymer with the structural unit represented by Chemical Formula 1 and the structural unit represented by Chemical Formula 2 in the ink are the same as those described above in Polymer and Copolymer.

### Water

Water contained in the ink of the present disclosure is not particularly limited and can be suitably selected to suit to a particular application.

The proportion of water mentioned above is not particularly limited and it can be suitably selected to suit to a particular application. It is preferably from 10 to 90 percent by mass and more preferably from 20 to 60 percent by mass to the entire of ink to quickly dry the ink and reliably discharge it.

### Coloring Material

There is no specific limitation to the coloring material for use in the ink of the present disclosure and it can be suitably selected to suit to a particular application, including dyes and pigments, for example. A mixed crystal can also be used as the coloring material.

### Pigment

The pigment mentioned above is not particularly limited and can be suitably selected to suit to a particular application. It includes, but is not limited to, black pigments, yellow pigments, magenta pigments, cyan pigments, white pigments, green pigments, orange pigments, and gloss or metallic pigments of gold, silver, and others.

Specific examples of the white pigments include, but are not limited to, titanium oxide, iron oxide, calcium oxide, barium sulfate, and aluminum hydroxide.

The pigment includes an inorganic pigment and organic pigment.

The inorganic pigment mentioned above is not particularly limited and can be suitably selected to suit to a particular application. Examples include, but are not limited to, titanium oxide, iron oxide, calcium oxide, barium sulfate, aluminum hydroxide, barium yellow, cadmium red, and chrome yellow, carbon black available from known methods such as contact methods, furnace methods, and thermal methods can be used.

The organic pigment is not particularly limited and can be suitably selected to suit to a particular application.

Specific examples include, but are not limited to, azo pigments, polycyclic pigments (e.g., phthalocyanine pigments, perylene pigments, perinone pigments, anthraquinone pigments, quinacridone pigments, dioxazine pigments, indigo pigments, thioindigo pigments, isoindolinone pigments, and quinophthalone pigments), dye chelates (e.g., basic dye type chelates and acid dye type chelates), nitro pigments, nitroso pigments, and aniline black.

Of these pigments, pigments with high affinity with solvents are preferable. In addition, resin hollow particles or inorganic hollow particles can be used.

Examples of the pigment include, but are not limited to, the following resins.

Specific examples of the black pigment include, but are not limited to, carbon black (C.I. Pigment Black 7) such as furnace black, lamp black, acetylene black, and channel black, metals such as copper and iron (C.I. Pigment Black 11), and organic pigments such as aniline black (C.I. Pigment Black 1).

Specific examples of the white pigment include, but are not limited to, titanium oxide, titanium dioxide, and resin hollow particles.

Specific examples of the color pigment include, but are not limited to, C. I. I. pigment yellow 1, C. I. pigment yellow 3, C. I. pigment yellow 12, C. I. pigment yellow 13, C. I. pigment yellow 14, C. I. pigment yellow 17, C. I. pigment yellow 24, C. I. pigment yellow 34, C. I. pigment yellow 35, C. I. pigment yellow 37, C. I. pigment yellow 42 (yellow iron oxide), C. I. pigment yellow 53, C. I. pigment yellow 55, C. I. pigment yellow 74, C. I. pigment yellow 81, C. I. pigment yellow 83, C. I. pigment yellow 95, C. I. Pigment Yellow 97 C. I. Pigment Yellow 98 C. I. Pigment Yellow 100 C. I. Pigment Yellow 101 C. I. Pigment Yellow 104 C. I. Pigment Yellow 108 C. I. Pigment Yellow 109 C. I. Pigment Yellow 110 C. I. Pigment Yellow 117 C. I. Pigment Yellow 120 C. I. Pigment Yellow 138 C. I. Pigment Yellow 150 C. I. Pigment Yellow 153 C. I. Pigment Yellow 155 C. I. Pigment Yellow 180 C. I. Pigment Yellow 185 C. I. Pigment Yellow 213 C. I. Pigment Orange 5 C. I. Pigment Orange 13 C. I. Pigment Orange 16 C. I. Pigment Orange 17 C. I. Pigment Orange 36, C. I. Pigment Orange 43, C. I. Pigment Orange 51, C. I. Pigment Red 1, C. I. Pigment Red 2, C. I. Pigment Red 3, C. I. Pigment Red 5, C. I. Pigment Red 17, C. I. Pigment Red 22, C. I. Pigment Red 23, C. I Pigment Red 31, C. I Pigment Red 38, C. I. Pigment Red 48: 2 (Permanent Red 2B (Ca)), C. I. Pigment Red 48: 3, C. I Pigment Red 48: 4, C. I. Pigment Red 49: 1, C. I. Pigment Red 52: 2, C. I. Pigment Red 53: 1, C. I Pigment Red 57: 1 (Brilliant Carmine 6B), C. I. Pigment Red 60: 1, C. I. Pigment Red 63: 1, C. I Pigment Red 63: 2, C. I. Pigment Red 64: 1, C. I. Pigment Red 81, C. I. Pigment Red 83, C. I. Pigment Red 88, C. I Pigment Red 101 (red iron oxide), C. I. Pigment Red 104, C. I. Pigment Red 105, C. I. Pigment Red 106, C. I. Pigment Red 108 (cadmium red), C. I. Pigment Red 112, C. I. Pigment Red 114, C. I. Pigment Red 122 (quinacridone magenta), C. I. Pigment Red 123, C. I. Pigment Red 146, C. I. Pigment Red 149, C. I. Pigment Red 166, C. I. Pigment Red 168, C. I. Pigment Red 170, C. I. Pigment Red 172, C. I. Pigment Red 177, C. I. Pigment Red 178, C. I. Pigment Red 179, C. I Pigment Red 184, C. I. Pigment Red 185, C. I. Pigment Red 190, C. I. Pigment Red 193, C. I Pigment Red 202, C. I. Pigment Red 207, C. I. Pigment Red 208, C. I. Pigment Red 209, C. I Pigment Red 213, C. I. Pigment Red 219, C. I. Pigment Red 224, C. I. Pigment Red 254, C. I. Pigment Red 264, C. I. Pigment Violet 1 (Rhodamine Lake), C. I. Pigment Violet 3, C. I. Pigment Violet 5: 1, C. I. Pigment Violet 16, C. I. Pigment Violet 19, C. I. Pigment Red 23, C. I. Pigment Violet 38, C. I. Pigment Blue 1, C. I Pigment Blue 2, C. I. Pigment Blue 15 (Phthalocyanine Blue), C. I. Pigment Blue 15: 1, C. I. Pigment Blue 15: 2, C. I. Pigment Blue 15: 3, C. I. Pigment Blue 15: 4 (Phthalocyanine Blue), C. I. Pigment Blue 16, C. I. Pigment Blue 17: 1, C. I. Pigment Blue 56, C. I. Pigment Blue 60, C. I. Pigment Blue 63, C. I. Pigment Green 1, C. I. Pigment Green 4, C. I. Pigment Green 7, C. I. Pigment Green 8, C. I. Pigment Green 10, C. I. Pigment Green 17, C. I. Pigment Green 18, and C. I. Pigment Green 36.

Of these, C. I. Pigment Red 146, C. I. Pigment Red 202, C. I. Pigment Red 208, and C. I. Pigment Violet 19 are preferable as the magenta pigment while C. I. Pigment Yellow 17 and C. I. Pigment 180 are preferable as the yellow pigment.

### Dyes

The dye mentioned above is not particularly limited and can be suitably selected to suit to a particular application. It includes an acidic dye, direct dye, reactive dye, and basic dye.

These can be used alone or in combination.

Specific examples of the dye include, but are not limited to, C. I. Acid Yellow 17, C. I. Acid Yellow 23, C. I. Acid Yellow 42, C. I. Acid Yellow 44, C. I. Acid Yellow 79, C. I. Acid Yellow 142, C. I. Acid Red 52, C. I. Acid Red 80, C. I. Acid Red 82, C. I. Acid Red 249, C. I. Acid Red 254, C. I. Acid Red 289, C. I. Acid Blue 9, C. I. Acid Blue 45, C. I. Acid Blue 249, C. I. Acid Black 1, C. I. Acid Black 2, C. I. Acid Black 24, C. I. Acid Black 94, C. I. Food Black 1, C. I. Food Black 2, C. I. Direct Yellow 1 C. I. Direct Yellow 12 C. I. Direct Yellow 24 C. I. Direct Yellow 33 C. I. Direct Yellow 50 C. I. Direct Yellow 55 C. I. Direct Yellow 58 C. I. Direct Yellow 86 C. I. Direct Yellow 132 C. I. Direct Yellow 142 C. I. Direct Yellow 144 C. I. Direct Yellow 173 C. I. Direct Red 1 C. I. Direct Red 80 C. I. Direct Red 81 C. I. Direct Red 225 C. I. Direct Red 227 C. I. Direct Blue 1 C. I. Direct Blue 2 C. I. Direct Blue 15, C. I. Direct Blue 71, C. I. Direct Blue 86, C. I. Direct Blue 87, C. I. Direct Blue 98, C. I. Direct Blue 165, C. I. Direct Blue 199, C. I. Direct Blue 202, C. I. Direct Black 19, C. I. Direct Black 38, C. I. Direct Black 51, C. I. Direct Black 71, C. I. Direct Black 154, C. I. Direct Black 168, C. I. Direct Black 171, C. I. Direct Black 195, C. I. Reactive Red 14, C. I. Reactive Red 32, C. I. Reactive Red 55, C. I. Reactive Red 79, C. I. Reactive Red 249, C. I. Reactive Black 3, C. I. Reactive Black 4, and C. I. Reactive Black 35.

The coloring material for use in the present disclosure is preferably a pigment because it has an excellent absorption to the polymer or the copolymer of the present disclosure and an excellent water resistance and weather resistance. In the case of the white pigment, titanium oxide and barium sulfate are preferable to achieve excellent white coverage with a preference of titanium oxide over barium sulfate. Additionally, titanium oxide is preferable to enhance storage stability of a coloring material dispersion, storage stability of ink, and re-dispersibility of ink.

The proportion of the coloring material contained in the ink of the present disclosure is not particularly limited and can be suitably selected to suit to a particular application. It is preferably from 0.1 to 15 percent by mass and more preferably from 10 to 15 percent by mass to the entire of ink to enhance the image density and achieve a good fixability and discharging stability.

### Other Components

The other optional components are not particularly limited and they can be selected to suit to a suitable application. Examples include, but are not limited to, other resins A, water, organic solvents, additives, radical polymerization initiators, and chain transfer agents.

### Other Resin A

The ink of the present disclosure may contain other resins A different from the polymer and copolymers.

The other resin A is not particularly limited and can be suitably selected to suit to a particular application. Examples include, but are not limited to, urethane resins, polyester resins, acrylic-based resins, vinyl acetate-based resins, styrene-based resins, butadiene-based resins, styrene-butadiene-based resins, vinylchloride-based resins, acrylic styrene-based resins, and acrylic silicone-based resins.

These can be used alone or in combination.

Resin particles consisting of the other resin A can be used as the other resin A. The resin particle can be synthesized or procured.

The volume average particle diameter (mean volume diameter) of the resin particle is not particularly limited and can be suitably selected to suit to a particular application. The volume average particle diameter is preferably from 10 to 1,000 nm, more preferably from 10 to 200 nm, and particularly preferably from 10 to 100 nm to achieve good fixability and image robustness.

The average particle diameter of the resin particle can be measured by using a device such as a particle size analyzer (Nanotrac Wave-UT151, available from MicrotracBEL Corp.).

### Organic Solvent

The ink of the present disclosure may contain an organic solvent. The organic solvent can be a hydrophilic organic solvent as the polymer and copolymer exhibit water solubility in the ink.

The organic solvent is not particularly limited and can be suitably selected to suit to a particular application.

Specific examples include, but are not limited to: polyhydric alcohols such as ethylene glycol, diethylene glycol, 1,2-propanediol, 1,3-propanediol, 1,2-butanediol, 1,3-butanediol, 1,4-butanediol, 2,3-butanediol, 3-methyl-1,3-butane diol, triethylene glycol, polyethylene glycol, polypropylene glycol, 1,2-pentanediol, 1,3-pentanediol, 1,4-pentanediol, 2,4-pentanediol, 1,5-pentanediol, 1,2-hexanediol, 1,6-hexanediol, 1,3-hexanediol, 2,5-hexanediol, 1,5-hexanediol, glycerin, 1,2,6-hexanetriol, 2-ethyl-1,3-hexanediol, ethyl-1,2,4-butane triol, 1,2,3-butanetriol, 2,2,4-trimethyl-1,3-pentanediol, and petriol; polyol alkyl ethers such as ethylene glycol monoethyl ether, ethylene glycol monobutyl ether, diethylene glycol monomethyl ether, diethylene glycol monoethyl ether, diethylene glycol monobutyl ether, tetraethylene glycol monomethyl ether, and propylene glycol monoethyl ether; polyol aryl ethers such as ethylene glycol monophenyl ether and ethylene glycol monobenzyl ether; nitrogen-containing heterocyclic compounds such as 2-pyrrolidone, N-methyl-2-pyrrolidone, N-hydroxyethyl-2-pyrrolidone, 1,3-dimethyl-2-imidazolidinone, ε-caprolactam, and γ-butyrolactone; amides such as formamide, N-methylformamide, N,N-dimethylformamide, 3-methoxy-N,N-dimethyl propioneamide, and 3-buthoxy-N,N-dimethyl propioneamide; amines such as monoethanolamine, diethanolamine, and triethylamine; sulfur-containing compounds such as dimethyl sulfoxide, sulfolane, and thiodiethanol; propylene carbonate, and ethylene carbonate.

Triethylene glycol monobutyl ether is preferable if the organic solvent is used as a penetrant.

The inclusion of triethylene glycol monobutyl ether in the ink allows for adjusting the permeability to fabric as a printing medium mentioned later, thereby resolving issues such as excessive ink penetration leading to poor image quality on the fabric.

Ethylene glycol and glycerin are preferable if the organic solvent is used as a humectant. Ethylene glycol is relatively inexpensive and has high humectant properties, resulting in improved ink discharging performance. Additionally, a dispersant with high hydrophilicity can improve the storage stability of the ink. Glycerin, having a higher boiling point compared to other organic solvents, can improve the ink discharging stability.

A water-soluble organic solvent with a boiling point of 250 or lower degrees C. is preferred, as it not only acts as a humectant but also enhances the drying properties.

A glycol ether compound and a polyol compound containing 8 or more carbon atoms are suitable organic solvents for enhancing ink penetration into paper media.

Specific examples of the polyol compounds containing 8 or more carbon atoms include, but are not limited to, 2-ethyl-1,3-hexanediol and 2,2,4-trimethyl-1,3-pentanediol.

The proportion of the organic solvent mentioned above in the ink is not particularly limited and can be suitably selected for specific applications. Preferably, it comprises from 10 to 60 percent by mass, more preferably from 20 to 70 percent by mass, and furthermore preferably from 45 to 65 percent by mass of the total ink mass to facilitate quick drying and reliable discharging of the ink.

### Additive

The additive mentioned above is not particularly limited and it can be suitably selected to suit to a particular application. Examples include, but are not limited to, water, a surfactant, defoaming agent, preservatives and fungicides, pH regulator, and corrosion inhibitor, which are used as the other components.

### Surfactant Used as Other Component

The surfactant used as the other component is not particularly limited and can be suitably selected to suit to a particular application. It includes, but is not limited to, a silicone-based surfactant, a fluorochemical surfactant, anionic surfactant, nonionic surfactant, and amphoteric surfactant.

The term ‘surfactant used as other component’ in the specification refers to a surfactant contained in the ink of the present disclosure as the other component, excluding the ‘other polymerizable monomer’ mentioned above,

### Silicone-Based Surfactant

There is no specific limitation to the silicone-based surfactant and it can be suitably selected to suit to a particular application. Of these, silicone-based surfactants that are not decomposed in a high pH range of 11 to 14 are preferable.

Specific examples of the silicone-based surfactant that are not decomposed in a high pH environment of 11 to 14 include, but are not limited to, side-chain modified polydimethyl siloxane, both-terminal modified polydimethyl siloxane, one-terminal-modified polydimethyl siloxane, and side chain both-terminal modified polydimethyl siloxane. Of these, a polyether-modified silicone-based surfactant with a polyoxyethylene or polyoxyethylene-polyoxypropylene group as a modifying group is preferable to enhance hydrophilicity and increasing solubility in water.

These can be used alone or in combination.

The polyether-modified silicon-based surfactant is not particularly limited and it can be suitably selected to suit to a particular application. One such surfactant is a compound in which the polyalkylene oxide structure represented by the following Chemical Formula S-1 is introduced into the side chain of the Si site of dimethyl polysiloxane.

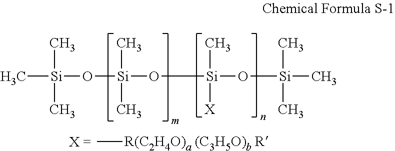

In Chemical Formula S-1, “m”, “n”, “a”, and “b” each, respectively independently represent integers, R represents an alkylene group, and R′ represents an alkyl group.

Polyether-modified silicone-containing surfactant can be synthesized or procured. Specific examples of the products of the polyether-modified silicone-based surfactant include, but are not limited to, KF-618, KF-642, and KF-643 (all available from Shin-Etsu Chemical Co., Ltd.), EMALEX-SS-5602 and EMALEX-SS-1906EX (both available from NIHON EMULSION Co., Ltd.), FZ-2105, FZ-2118, FZ-2154, FZ-2161, FZ-2162, FZ-2163, and FZ-2164 (all available from Dow Corning Toray Co., Ltd.), BYK-33 and BYK-387 (both available from BYK Chemie GmbH), and TSF4440, TSF4452, and TSF4453 (all available from Toshiba Silicone Co. Ltd.).

The silicone-based surfactant can be synthesized or procured. Products thereof can be procured from manufacturers such as BYK-Chemie GmbH, Shin-Etsu Silicone Co., Ltd., Dow Corning Toray Co., Ltd., NIHON EMULSION Co., Ltd., and Kyoeisha Chemical Co., Ltd.

### Fluorochemical Surfactant

The fluorochemical surfactant mentioned above is not particularly limited and can be suitably selected to suit to a particular application. It is preferably a fluorine-substituted compound having 2 to 16 carbon atoms and more preferably a fluorine-substituted compound having 4 to 16 carbon atoms.

The fluorochemical surfactant mentioned above is not particularly limited and can be suitably selected to suit to a particular application.

Specific examples include, but are not limited to, a perfluoroalkyl sulfonic acid compound, perfluoroalkyl carboxylic acid compound, perfluoroalkyl phosphoric acid ester compound, adduct of perfluoroalkyl ethylene oxide, and polyoxyalkylene ether polymer compound having a perfluoroalkyl ether group in its side chain because of their low foaming property.

Specific examples of the perfluoroalkyl sulfonic acid compound include, but are not limited to, perfluoroalkyl sulfonic acid and salts of perfluoroalkyl sulfonic acid.

Specific examples of the perfluoroalkyl carbonic acid compound include, but are not limited to, perfluoroalkyl carbonic acid and salts of perfluoroalkyl carbonic acid.

Specific examples of the polyoxyalkylene ether polymer compound having a perfluoroalkyl ether group in its side chain include, but are not limited to, sulfuric acid ester salts of polyoxyalkylene ether polymer having a perfluoroalkyl ether group in its side chain, and salts of polyoxyalkylene ether polymers having a perfluoroalkyl ether group in its side chain.

Fluorochemical surfactant represented by the following Chemical Formulae F-1 and F-2 are more preferable.

CF₃CF₂(CF₂CF₂)ₘ—CH₂CH₂O(CH₂CH₂O)ₙH Chemical Formula F-1

In the compound represented by Chemical Formula F-1, “m” is preferably 0 or an integer of from 1 to 10 and “n” is preferably 0 or an integer of from 1 to 40.

CₙF₂ₙ₊₁—CH₂CH(OH)CH₂—O—(CH₂CH₂O)ₐ—Y Chemical Formula F-2

In the compound represented by Chemical Formula F-2, Y represents H or CₘF₂ₘ₊₁, where n represents an integer of from 1 to 6, or CH₂CH(OH)CH₂—CₘF₂ₘ₊₁, where m represents an integer of from 4 to 6, or CₚH₂ₚ₊₁, where p is an integer of from 1 to 19. n represents an integer of from 1 to 6. a represents an integer of from 4 to 14.

Counter ions of salts in these fluoro-surfactants are Li, Na, K, NH₄, NH₃CH₂CH₂OH, NH₂(CH₂CH₂OH)₂, and NH(CH₂CH₂OH)₃, for example.

The fluorochemical surfactant can be synthesized and procured. Specific examples of the procurable products include, but are not limited to, SURFLON S-111, SURFLON S-112, SURFLON S-113, SURFLON S-121, SURFLON S-131, SURFLON S-132, SURFLON S-141, and SURFLON S-145 (all available from AGC Inc.); FLUORAD FC-93, FC-95, FC-98, FC-129, FC-135, FC-170C, FC-430, and FC-431 (all available from Sumitomo 3M Limited); MEGAFACE F-470, F-1405, and F-474 (all available from DIC CORPORATION); ZONYL™ TBS, FSP, FSA, FSN-100, FSN, FSO-100, FSO, FS-300, and UR, CAPSTONE® FS-30, CAPSTONE® FS-31, CAPSTONE® FS-3100, CAPSTONE® FS-34, and CAPSTONE® FS-35 (all available from The Chemours Company); FT-110, FT-250, FT-251, FT-400S, FT-150, and FT-400SW (all available from NEOS COMPANY LIMITED); POLYFOX PF-136A, PF-156A, PF-151N, PF-154, and PF-159 (available from OMNOVA SOLUTIONS INC.), and UNIDYNE DSN-403N (available from DAIKIN INDUSTRIES). Of these, FS-3100, FS-34, and FS-300 (all available from The Chemours Company), FT-110, FT-250, FT-251, FT-400S, FT-150, and FT-400SW (all available from NEOS COMPANY LIMITED), Polyfox PF-151N (available from OMNOVA SOLUTIONS) and Unidyne DSN-403N (available from DAIKIN INDUSTRIES, LTD.) are preferable to achieve good printing quality, particularly significantly enhancing color development, and permeability, wettability, and uniform dyeing to paper.

### Amphoteric Surfactant

The amphoteric surfactant is not particularly limited and can be suitably selected to suit to a particular application.

Specific examples include, but are not limited to, lauryl aminopropionic acid salts, lauryl dimethyl betaine, stearyl dimethyl betaine, and lauryl dihydroxyethyl betaine.

These can be used alone or in combination.

### Nonionic Surfactant

The nonionic surfactant is not particularly limited and it can be suitably selected to suit to a particular application.

Specific examples include, but are not limited to, polyoxyethylene alkyl phenyl ethers, polyoxyethylene alkyl esters, polyoxyethylene alkyl amines, polyoxyethylene alkyl amides, polyoxyethylene propylene block polymers, sorbitan aliphatic acid esters, polyoxyethylene sorbitan aliphatic acid esters, and adducts of acetylene alcohol with ethylene oxides.

These can be used alone or in combination.

### Anionic Surfactant

The anionic surfactant is not particularly limited and can be suitably selected to suit to a particular application. Specific examples include, but are not limited to, salts such as a polyoxyethylene alkylether acetate, a dodecylbenzene sulfonate, a laurate, and a polyoxyethylene alkylether sulfate.

These can be used alone or in combination.

The proportion of the surfactant used as the other component is not particularly limited and it can be suitably selected to suit a particular application. It is preferably from 0.001 to 5 percent by mass and more preferably from 0.05 percent by mass to 5 percent by mass to the total ink mass to achieve good wettability and discharging stability and enhance the image quality.

### Defoaming Agent

The surfactant used as the other component can be used as a defoaming agent.

The defoaming agent is not particularly limited and it can be suitably selected to suit to a particular application. It includes, but is not limited to, a silicon-based defoaming agent, polyether-based defoaming agent, and aliphatic acid ester-based defoaming agent. Of these, silicone-based defoaming agents are preferable to enhance the ability of braking foams.

Those defoaming agents can be used alone or in combination.

### Preservatives and Fungicides

The preservatives and fungicides are not particularly limited and can be suitably selected to suit to a particular application. One specific example is 1,2-benzisothiazoline-3-one.

### pH Regulator

The pH regulator is not particularly limited as long as it can adjust pH not lower than 7 and it can be suitably selected to suit to a particular application.

Specific examples include, but are not limited to, amines such as diethanol amine and triethanol amine. Of these, triethanol amine, which is inexpensive, is preferable, The proportion of the pH adjuster is preferably 0.5 or less percent by mass to the total ink mass, and more preferably from 0.25 to 0.5 percent by mass for ink storage stability.

### Radical Polymerization Initiator

A radical polymerization initiator may be used in the process of forming the copolymer of the present disclosure.

The radical polymerization initiator is not particularly limited and can be suitably selected to suit to a particular application.

Specific examples include, but are not limited to, peroxyketal, hydroperoxide, dialkyl peroxide, diacyl peroxide, peroxydicarbonate, peroxyester, cyano-based azobisisobutyronitrile, azobis (2-methylbutyronitrile), azobis (2,2′-isovaleronitrile), and non-cyano-based dimethyl-2,2′-azobisisobutyrate. Of these, organic peroxides and azo-based compounds are preferable and azo-based compounds are more preferable because their molecular weight can be easily adjusted and they are decomposed at low temperatures.

The proportion of the radical polymerization initiator is not particularly limited and can be suitably selected to suit to a particular application. It is preferably from 1 to 10 percent by mass to the sum of polymerizable monomers. The term ‘polymerizable monomer’ refers to all of the first monomer, the second monomer, and the third monomer.

### Chain Transfer Agent

To control the molecular weight of the copolymer in the present disclosure, a chain transfer agent is optionally added.

The chain transfer agent is not particularly limited and can be suitably selected to suit to a particular application.

Specific examples include, but are not limited to, mercapto acetate, mercapto propionate, 2-propane thiol, 2-meracapto ethanol, thiophenol, dodecyl mercaptane, 1-dodecane thiol, and thioglycerol.

### Ink's Property

Properties of the ink of the present disclosure are not particularly limited and they can be suitably selected to suit to a particular application. The ink preferably has properties such as viscosity, surface tension, and pH in the following ranges.

The ink preferably has a viscosity of from 5 to 30 mPa·s and more preferably from 5 to 25 mPa·s at 25 degrees C. to enhance the print density and text quality and achieve good dischargeability. Viscosity can be measured with equipment such as a rotatory viscometer, RE-80L, available from TOKI SANGYO CO., LTD. The conditions for measuring viscosity are as follows:
Standard cone rotor (1°34′×R24)
Sample liquid amount: 1.2 mL
Rate of rotations: 50 rotations per minute (rpm)
25 degrees C.
Measuring time: three minutes.

The surface tension of the ink of the present disclosure is preferably 35 mN/m or less and more preferably 32 mN/m or less at 25 degrees C. because the ink suitably levels on a printing medium and the ink quickly dries.

pH of the ink is preferably from 7 to 12 and more preferably from 8 to 11 to prevent corrosion of the metal material in contact with liquid.

Regarding qualitatively and quantitatively analysis of organic solvents, polymers, copolymers, pigments, and other components contained in the ink of the present disclosure.

one such method is gas chromatography-mass spectrometry (GC-MS).

GCMS is conducted by GCMS-QP2020NX (available from Shimadzu Corporation), for example. The moisture contained in the ink can be measured by an available method, such as quantitative analysis of the volatile components by GC-MS or mass variation by thermogravimeter-differential thermal analysis (TG-DTA).

### Ink Container

The ink of the present disclosure can be accommodated in an ink container for use in printing. In the specification, the ink container accommodating the ink of the present disclosure is also referred to as an ink accommodating container.

The ink container is not particularly limited. One such container is a known ink cartridge for an inkjet printer.

The ink container is easily stored and conveyed with a handle of ease and can be detachably attached to both an ink cartridge and an image forming device for ink replenishment.

The ink container is not particularly limited and can be suitably selected from known containers. One such container is a container with a cap.

The shape of the ink container is not particularly limited and can be suitably selected to suit to a particular application. Preferably, it takes a cylindrical shape. Additionally, this ink container features spiral irregularities on its inner peripheral surface, enabling the movement of ink towards the discharging aperture through rotation. Preferably, some or all of these spiral irregularities also function as a bellows.

The material of the ink container is not particularly limited and it can be suitably selected to suit to a particular application. Preferably, a resin such as polyester resin, polyethylene resin, polypropylene resin, polystyrene resin, polyvinyl chloride resin, polyacrylic acid, ABS resin containing a polycarbonate resin component, or polyacetal resin is used to achieve good dimensional accuracy.

The size and structure of the ink container is not particularly limited and it can be suitably selected to suit to a particular application.

### Image Forming Device and Image Forming Method

The image forming device of the present disclosure includes an ink container accommodating the ink of the present disclosure, a device for discharging the ink to a printing medium, and other optional devices.

The image forming method of the present disclosure includes discharging the ink of the present disclosure to a printing medium to form an image thereon and other optional processes.

The image forming method can be conducted with the image forming device.

### Discharging Device and Discharging Process

The discharging device discharges the ink accommodated in the ink container mentioned above to a printing medium.

The discharging device discharges the ink accommodated in the ink container mentioned above to a printing medium.

The ink discharging is suitably conducted with the discharging device.

The discharging device is not particularly limited and it can be a known ink discharging device such as an inkjet device.

### Other Optional Unit and Other Optional Step

The other optional devices are not particularly limited and can be suitably selected to suit to a particular application.

Specific examples include, but are not limited to, a pre-processing unit, a post-processing unit, a heating device, a drying device, and a device for feeding, conveying, and ejecting a printing medium.

The other optional processes are not particularly limited and they can be suitably selected to suit to a particular application. Specific examples include, but are not limited to, pre-processing, post-processing, heating, drying, and processes relating to feeding, conveying, and ejecting a printing medium.

In addition, the other processes are suitably conducted by the other corresponding devices.

### Pre-Processing Unit and Pre-Processing Process

The pre-processing unit applies a pre-processing fluid to a printing medium before the ink is applied thereto.

In the pre-processing process, a pre-processing fluid is applied to a printing medium before the ink is applied thereto.

The pre-processing process can be suitably conducted with the pre-processing unit.

As an aspect of a pre-processing device equipped with the pre-processing unit, as in the case of the ink such as black (K), cyan (C), magenta (M), yellow (Y), and white (W), the pre-processing device further includes a liquid accommodating unit containing the pre-processing fluid mentioned above and a liquid discharging head for discharging the pre-processing fluid according to inkjet printing.

The pre-processing unit is not particularly limited and it can be suitably selected to suit to a particular application. It includes, but is not limited to, a unit that stores the pre-processing fluid in an ink container like ink and applies the pre-processing fluid to a printing medium by inkjetting, a unit utilizing blade coating, a unit utilizing roll coating, and a unit utilizing spray coating.

The pre-processing liquid includes a flocculant, an organic solvent, water, and optional materials such as a surfactant, a defoaming agent, a pH regulator, a preservatives and fungicides, and a corrosion inhibitor.

For the organic solvent, the surfactant, the defoaming agent, the pH regulator, the preservatives and fungicides, and the corrosion inhibitor, the same materials as those for use in ink can be used. Materials for use in known processing fluid can be also used.

The flocculant is not particularly limited and it can be suitably selected to suit to a particular application. Examples include, but are not limited to, a water-soluble cationic polymer, an acid, and a polyvalent metal salt.

### Post-Processing Unit and Post-Processing Process

The post-processing unit applies a post-processing fluid to a printing medium after the ink is applied thereto.

In the post-processing process, a post-processing fluid is applied to a printing medium after the ink is applied thereto.

The post-processing process is suitably conducted with the post-processing unit.

As an aspect of the post-processing device including the post-processing unit, as in the case of the ink such as black (K), cyan (C), magenta (M), yellow (Y), and white (W), the post-processing device may further include a liquid accommodating unit containing a post-processing fluid and a liquid discharging head for discharging the post-processing fluid according to inkjet printing.

The post-processing unit is not particularly limited and it can be suitably selected to suit to a particular application. It includes, but is not limited to, a unit that stores the post-processing fluid in an ink container like ink and applies the post-processing fluid to a printing medium by inkjetting, a unit utilizing blade coating, a unit utilizing roll coating, and a unit utilizing spray coating.

The post-processing fluid is not particularly limited as long as it can form a transparent layer. Materials such as an organic solvent, water, a resin, a surfactant, a defoaming agent, a pH regulator, preservatives and fungicides, and a corrosion inhibitor are selectively chosen and mixed as needed to produce the post-processing fluid. The post-processing fluid can be applied to the entire printing region formed on a printing medium or only the region on which an ink image is formed.

### Heating Device and Heating Process and Drying Device and Drying Process

The heating device heats the print surface and/or the opposite surface of a printing medium.

The heating process includes heating the print surface and/or the opposite surface of a printing medium.

The heating process can be suitably conducted with the heating device.

The drying device dries the print surface and/or the opposite surface of a printing medium.

The drying process includes drying the print surface and/or the opposite surface of a printing medium.

The drying process can be suitably conducted by the drying device.

The heating device and the drying device are not particularly limited. It includes, but is not limited to a fan heater or an infra-red heater. It is possible to heat and dry a printing medium before, during, and after printing.

In addition, the image forming device and the image forming method are not limited to those for producing meaningful visible images such as text and figures with ink. Devices for creating patterns like geometric design and 3D images are included.

In addition, the image forming device includes both a serial type device with a movable liquid discharging head and a line type device with a fixed liquid discharging head, unless otherwise specified.

Furthermore, other than a desktop type printer, this image forming device includes a device capable of printing images on a wide printing medium of, for example, A0 size, and a continuous printer capable of using continuous paper reeled in a roll-like form as a printing medium.

### Printing Medium

The term “printing medium” in the specification means a target on which printing is conducted with the ink of the present disclosure. The printing medium refers to an item to which the ink of the present disclosure or processing fluids can be temporarily or permanently attached.

The printing medium is not particularly limited and can be suitably selected to suit to a particular application. It includes, but is not limited to, plain paper, gloss paper, special paper, cloth, film, a transparent sheet, general printing paper, or a non-permeable substrate.

The term “non-permeable substrate” refers to a substrate with a surface that has low water permeability and low absorbency, including materials with numerous internal voids that are not open to the exterior. Quantitatively, it refers to a substrate in the Bristow method where the water absorption from contact initiation to 30 msec^{1/2} is 10 or less mL/mm².

The non-permeable substrate includes, but is not limited to, plastic films such as vinyl chloride resin film, polyethylene terephthalate (PET) film, polypropylene film, polyethylene film, and polycarbonate film.

The printing medium is not limited to a typical printing medium and suitably includes building materials such as wall paper, a floor material, and a tile, cloth for apparel such as T-shirts, textile, and leather. The configuration of the paths on which the printing medium is conveyed can be changed to use materials such as ceramics, glass, and metal.

### Printed Matter

Items on which images are formed with the ink of the present disclosure can be defined as printed matter.

The printed matter can be obtained with the image forming device executing the image forming method.

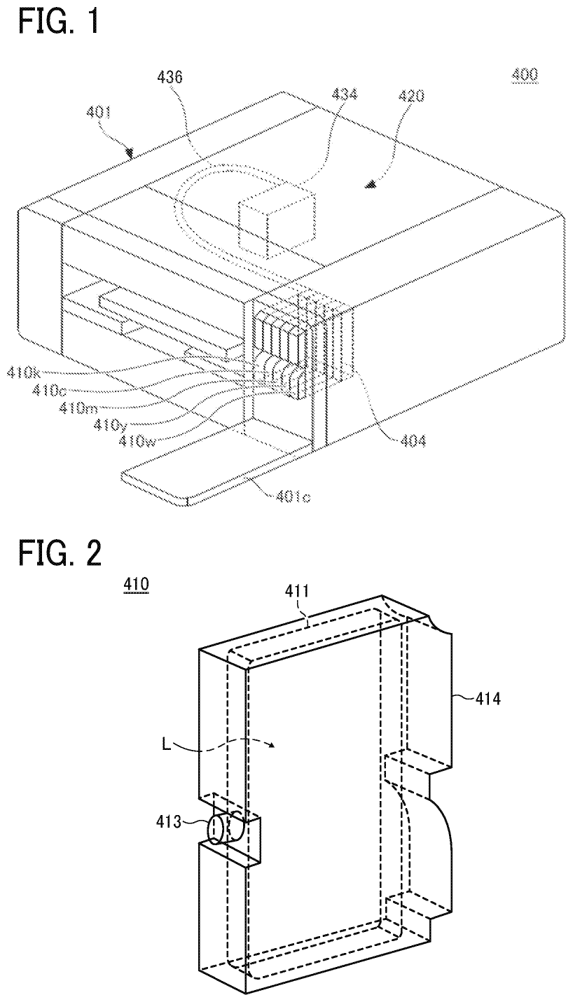

One example of the image forming device of the present disclosure is described with reference to FIG. 1 and FIG. 2. FIG. 1 is a diagram illustrating a perspective view of the same device. FIG. 2 is a diagram illustrating a perspective view of a tank. An image forming device 400 is a serial image forming device. An image forming device 400 includes a mechanical unit 420 inside an exterior 401. Each ink accommodating unit (ink container) 411 of each tank 410 (410k, 410c, 410m, 410y, 410W) for each color of black (K), cyan (C), magenta (M), yellow (Y), and white (W) is made of a packing member such as aluminum laminate film. The ink accommodating unit 411 is housed in, for example, a plastic container housing unit 414 and L represents liquid contained in the ink accommodating unit 41 containing liquid L. The tank 410 is used as an ink cartridge of each color.

A cartridge holder 404 is disposed on the rear side of the opening appearing when a cover 401c is opened. The cartridge holder 404 is detachably attached to the tank 410. This configuration enables each ink discharging outlet 413 of the tank 410 to communicate with a discharging head 434 for each color via a supplying tube 436 for each color so that the ink can be discharged from the discharging head 434 to a printing medium.

### Application Field

The ink of the present disclosure can be suitably applied to a printing device employing inkjet printing, such as a printer, facsimile machine, photocopier, multifunction peripheral (serving as a printer, a facsimile machine, and a photocopier), and solid freeform fabrication device such as a 3D printer and additive manufacturing device.

The usage of the ink of the present disclosure is not particularly limited and can be suitably selected to suit to a particular application. The ink can be applied to printed matter, a paint, a coating material, and foundation. The ink can be used to produce two-dimensional text and images. They also can be used as a material for solid fabrication for manufacturing a three-dimensional image (or solid freeform fabrication object).

The solid freeform fabrication object includes an object manufactured by repetitive coating of ink. In addition, the solid freeform fabrication object includes a mold-processed product manufactured by processing a structure having a substrate such as a printing medium to which the ink is applied.

Any known device can be used as the device for manufacturing a solid freeform fabrication object without a particular limit. For example, a device including a container, supplying device, discharging device, drier of ink, and others can be used.

The mold-processed product is manufactured from printed matter or a structure having a sheet-like form and film-like form by, for example, heating drawing or punching. The mold-processed product is suitably used to produce items surface-decorated after molding such as gauges or operation panels of vehicles, office machines, electric and electronic devices, and cameras.

### Backsheet for Solar Cell

The polymer having a structural unit represented by Chemical Formula 1 or the copolymer having a structural unit represented by Chemical Formula 1 and a structural unit represented by Chemical Formula 2 can be used as a resin contained in the protection layer of a backsheet for solar cell.

In other words, the backsheet for solar cell of the present disclosure is has a protection layer, which features a coated film made of the ink, and it may optionally contain other resins B. Furthermore, since the “ink” is the same as that described in Ink above, its description is omitted.

The backsheet for solar cell of the present disclosure can be placed on the rear side of a solar cell module to enhance weather resistance against light from both the light-receiving surface and the rear side.

The protection layer is preferably disposed on a substrate film. The substrate film is not particularly limited and can be selected to suit a specific application. Polyester film is preferred to enhance mechanical strength, dimensional stability, and thermal stability. Polyester film primarily composed of polyethylene terephthalate or polyethylene naphthalate is even more preferable.

The protection layer in the solar cell module may contain other resin B. The other resin B is not particularly limited and can be suitably selected to suit to a particular application. Acrylic-based resin is preferable and acrylic-based resin cross-linkable with isocyanate is more preferable to achieve excellent mechanical strength and resistance to weather.

The method of manufacturing the backsheet for solar cells is not particularly limited and can be suitably selected to fit a specific application. The backsheet can be manufactured using the following method, comprising 1 to 4 processes, for example:

Process 1: The polymer or the copolymer of the present disclosure is added to an organic solvent and dissolved while being stirred to obtain a solution. A coloring material is optionally slowly added to the solution during stirring followed by additional stirring.

Process 2: The resulting solution is then dispersed with a dispersing device and filtered with a membrane filter. The organic solvent is added as a balance to prepare a liquid for forming a protection layer.

Process 3: The liquid obtained is applied to the surface of a substrate using a wire bar, and then the liquid is dried until it reaches a specific thickness to form a protection layer.

Process 4: The protective layer obtained is aged to produce a backsheet for solar cells.

The organic solvent for use in the process 1 is not particularly limited and it can be suitably selected to suit to a particular application. It includes, but is not limited to, the organic solvent specified in the Ink section above and hexamethylene diisocyanate.

The coloring material for use in Process 1 is not particularly limited and can be suitably selected for a specific application. It includes, but is not limited to, the coloring materials specified in the Ink section above.

The dispersing device in Process 2 is not particularly limited and can be suitably selected for a specific application. A specific example is the big rotor BR-2, available from AS ONE Corporation. The condition of the dispersion is not particularly limited and it can be suitably selected to suit to a particular application. For example, the dispersion can be conducted at a rate of rotation of 90 rpm for a treatment time of five days.

The substrate in process 3 is not particularly limited and can be suitably selected for a specific application. One such substrate is the printing medium mentioned in the Image Forming Device and Image Forming Method sections above.

The “particular thickness” in Process 3 is not particularly limited and can be suitably selected for a specific application. For example, it can be 2 km.

The drying conditions in Process 3 are not particularly limited and can be suitably selected for a specific application. For example, the liquid can be dried at a temperature of 150 degrees C. for five minutes.

The condition of the aging in Process 4 is not particularly limited and it can be suitably selected to suit to a particular application. For example, the backsheet can be aged at 50 degrees C. for three days.

The terms of image forming, recording, and printing in the present specification represent the same meaning.

Also, printing media, media, and substrates in the present specification have the same meaning unless otherwise specified.

The terms of image forming, recording, and printing in the present disclosure represent the same meaning.

Also, recording media, media, and print substrates in the present disclosure have the same meaning unless otherwise specified.

Having generally described preferred embodiments of this disclosure, further understanding can be obtained by reference to certain specific examples which are provided herein for the purpose of illustration only and are not intended to be limiting. In the descriptions in the following examples, the numbers represent weight ratios in parts, unless otherwise specified.

### EXAMPLES

Next, the present disclosure is described in detail with reference to Examples but is not limited thereto. In Examples, the terms “parts” and “percent” refer to “parts by mass” and “percent by mass” unless otherwise specified.

The molecular weight of the polymers or copolymers obtained in Synthesis Examples, Examples, and Comparative Examples were measured by the following method under the following conditions.

### Method of Measuring Weight Average Molecular Weight

The weight average molecular weight of the polymer was measured by gel permeation chromatography (GPC) using the following devices in the conditions below:
Device: GPC-8320 GPC (available from TOSOH CORPORATION)
Column: TSK G2000 HXL and G4000 HXL (available from TOSOH CORPORATION)
Temperature: 40 degrees C.
Solvent: Tetrahydrofuran (THF)
Rate of flow: 0.6 mL/min.

One milliliter of a polymer with a concentration of 0.5 percent by mass was infused into the device, and the weight average molecular weight Mw of the polymer and the copolymer was calculated using the molecular weight calibration curve created based on monodisperse polystyrene standard samples from the molecular weight distribution of the polymer measured under the conditions specified above.

### Synthesis Example 1

### Synthesis of Monomer M-1

Ethylene glycol (31.03 g, 500 mmol, available from TOKYO CHEMICAL INDUSTRY CO., LTD.) was gradually added little by little to 11.77 g (120 mmol) of concentrated sulfuric acid (available from KOKUSAN CHEMICAL CO., LTD.), and the mixture was heated to 50 degrees C. Isonicotinic acid (12.31 g, 100 mmol, available from TOKYO CHEMICAL INDUSTRY CO., LTD.) was added little by little during stirring, and the resulting mixture was heated up to 120 degrees C. under stirring over 5 hours. After cooling to room temperature, 4N sodium hydroxide solution (available from Kanto Chemical Co., Inc.) was added during stirring to achieve a pH of 7. The resulting mixture was extracted twice with 150 ml of ethyl acetate (available from Kanto Chemical Co., Inc.). The organic phase isolated was rinsed twice with 150 ml of water and then dried over magnesium sulfate (available from Kanto Chemical Co., Inc.). The solvent was distilled away from the organic phase, and the residue was purified by column chromatography on silica gel using a mixture of hexane (available from Kanto Chemical Co., Inc.) and ethyl acetate (available from Kanto Chemical Co., Inc.) (volume ratio at 5:5 to 0:10) as the eluent to obtain 9.55 g of Intermediate 1.

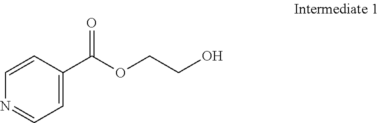 [SMILES: O=C(OCCO)c1ccncc1]

Then 8.36 g (50 mmol of Intermediate 1 was dissolved in 20 mL of dehydrated tetrahydrofuran (THF) (available from Kanto Chemical Co., Inc.). To the resulting solution, a solution containing 9.31 g (60 mmol) of methacrylic acid 2-isocyanatoethyl (available from Tokyo Chemical Industry Co. Ltd.) dissolved in 10 mL of dehydrated THF was added dropwise over 10 minutes, followed by stirring at 35 degrees C. for 12 hours. The resulting reaction solution was stripped of the solvent, and the residue was purified by column chromatography on silica gel using a mixture of hexane/ethyl acetate (volume ratio ranging from 5:5 to 0:10) as the eluent to obtain 11.55 g of Monomer M-1.

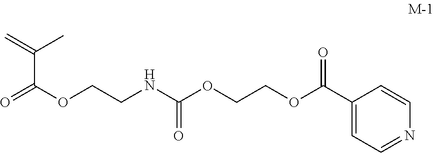 [SMILES: C=C(C)C(=O)OCCNC(=O)OCCOC(=O)c1ccncc1]

### Synthesis Example 2

### Synthesis of Monomer M-2

A total of 59.08 g (500 mmol) of 1,6-hexane diol (available from Tokyo Chemical Industry Co., Ltd.) was heated up to 80 degrees C., and then 11.77 g (120 mmol) of concentrated sulfuric acid was added little by little. Subsequently, 12.31 g (100 mmol) of isonicotinic acid was added little by little with stirring, and the mixture was heated up to 120 degrees C. under stirring over 5 hours. After cooling to room temperature, 4N sodium hydroxide solution was added with stirring until the pH reached 7. The mixture was extracted twice with 200 ml of ethyl acetate, and the organic phase obtained was washed twice with 200 ml of water. The isolated organic phase was then dried over magnesium sulfate. The solvent was distilled away from the organic phase, and the residue was purified by column chromatography on silica gel using a mixture of hexane (available from Kanto Chemical Co., Inc.) and ethyl acetate (available from Kanto Chemical Co., Inc.) (volume ratio ranging from 5:5 to 0:10) as the eluent to obtain 13.67 g of Intermediate 2.

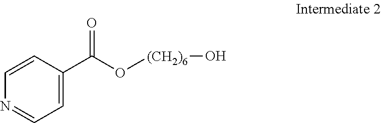

Then 11.16 g (50 mmol) of Intermediate 2 was dissolved in 20 mL of dehydrated THF. To the resulting solution, a solution containing 9.31 g (60 mmol) of methacrylic acid 2-isocyanatoethyl dissolved in 10 mL of dehydrated THF was added dropwise over 10 minutes, followed by stirring at 35 degrees C. for 12 hours. The resulting reaction solution was stripped of the solvent, and the residue was purified by column chromatography on silica gel using a mixture of hexane/ethyl acetate (volume ratio ranging from 5:5 to 0:10) as the eluent to obtain 13.34 g of Monomer M-2.

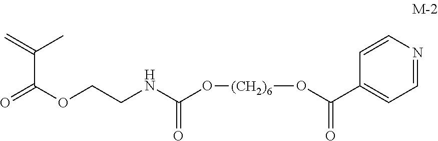

### Synthesis Example 3

### Synthesis of Monomer M-3

A total of 11.16 g (50 mmol) of Intermediate 2 was dissolved in 20 mL of dehydrated THF. To the resulting solution, a solution containing 12.68 g (60 mmol) of methacrylic acid 6-isocyanatohexyl ester (available from HongKong Chemhere Co., Ltd.) dissolved in 10 mL of dehydrated THE was added dropwise over 10 minutes, followed by stirring at 35 degrees C. for 12 hours. The resulting reaction solution was stripped of the solvent, and the residue was purified by column chromatography on silica gel using a mixture of hexane/ethyl acetate (volume ratio ranging from 5:5 to 0:10) as the eluent to obtain 13.34 g of Monomer M-3.

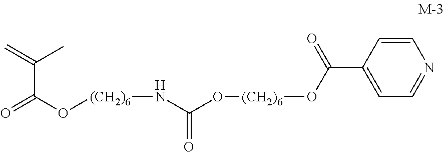

### Synthesis Example 4

### Synthesis of Monomer M-4

A total of 11.16 g (50 mmol) of Intermediate 2 was dissolved in 20 mL of dehydrated THF. To the resulting solution, a solution containing 16.05 g (60 mmol) of methacrylic acid (3-methyl-7,7-dimethyl-7-isocyanate) hexyl ester (available from HongKong Chemhere Co., Ltd.) dissolved in 10 mL of dehydrated THF was added dropwise over 10 minutes, followed by stirring at 35 degrees C. for 12 hours. The resulting reaction solution was stripped of the solvent, and the residue was purified by column chromatography on silica gel using a mixture of hexane/ethyl acetate (volume ratio ranging from 5:5 to 0:10) as the eluent to obtain 17.47 g of Monomer M-4.

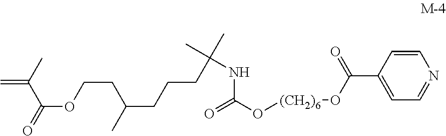

### Synthesis Example 5

### Synthesis of Monomer M-5

A total of 87.04 g (500 mmol) of 1,10-decane diol (available from Tokyo Chemical Industry Co., Ltd.) was heated up to 80 degrees C., and then 11.77 g (120 mmol) of concentrated sulfuric acid was added little by little. Subsequently, 12.31 g (100 mmol) of isonicotinic acid was added little by little with stirring, and the mixture was heated up to 120 degrees C. under stirring over 5 hours. After cooling to room temperature, 4N sodium hydroxide solution was added with stirring until the pH reached 7. The mixture was extracted twice with 200 ml of ethyl acetate, and the organic phase obtained was washed twice with 200 ml of water. The isolated organic phase was then dried over magnesium sulfate. The solvent was distilled away from the organic phase, and the residue was purified by column chromatography on silica gel using a mixture of hexane (available from Kanto Chemical Co., Inc.) and ethyl acetate (available from Kanto Chemical Co., Inc.) (volume ratio ranging from 5:5 to 0:10) as the eluent to obtain 14.55 g of Intermediate 3.

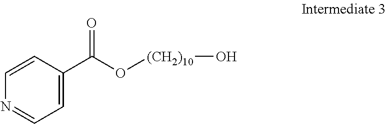

Then 13.97 g (50 mmol) of Intermediate 3 was dissolved in 20 mL of dehydrated THF. To the resulting solution, a solution containing 16.05 g (60 mmol) of methacrylic acid (3-methyl-7,7-dimethyl-7-isocyanate) hexyl ester (available from HongKong Chemhere Co., Ltd.) dissolved in 10 mL of dehydrated THF was added dropwise over 10 minutes, followed by stirring at 35 degrees C. for 12 hours. The resulting reaction solution was stripped of the solvent, and the residue was purified by column chromatography on silica gel using a mixture of hexane/ethyl acetate (volume ratio ranging from 5:5 to 0:10) as the eluent to obtain 16.23 g of Monomer M-5.

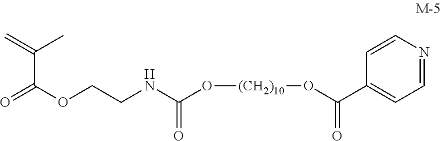

### Synthesis Example M-6

### Synthesis of Monomer M-6

To 50 mL of methyl ethyl ketone (available from by Kanto Chemical Co., Inc.), 9.51 g (100 mmol) of 4-hydroxypyridine, 21.73 g (120 mmol) of 6-bromo-1-hexanol (available from Tokyo Chemical Industry Co., Ltd.), and 27.64 g (200 mmol) of potassium carbonate (available from Kanto Chemical Co., Inc.) were added, and the mixture was held at reflux for 18 hours. After cooling to room temperature, the mixture was filtered, and the filtrate was distilled away. The residue was purified by column chromatography on silica gel using a mixture of hexane/ethyl acetate (volume ratio ranging from 5:5 to 0:10) as the eluent, yielding 15.12 g of Intermediate 4.

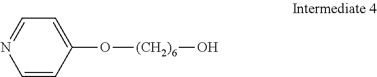

Then 9.77 g (50 mmol) of Intermediate 4 was dissolved in 20 mL of dehydrated THF. To the resulting solution, a solution containing 8.47 g (60 mmol) of acrylic acid 2-isocyanatoethyl ester (available from Tokyo Chemical Industry Co. Ltd.) dissolved in 10 mL of dehydrated THE was added dropwise over 10 minutes, followed by stirring at 35 degrees C. for 12 hours. The resulting reaction solution was stripped of the solvent, and the residue was purified by column chromatography on silica gel using a mixture of hexane/ethyl acetate (volume ratio ranging from 5:5 to 0:10) as the eluent to obtain 14.38 g of Monomer M-6.

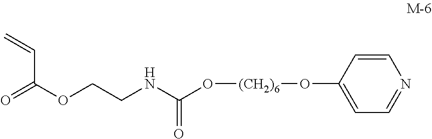

### Synthesis Example 7

### Synthesis of Monomer M-7

A total of 59.10 g (500 mmol) of 1,6-hexane diol (available from Tokyo Chemical Industry Co., Ltd.) was heated up to 80 degrees C., and then 11.77 g (120 mmol) of concentrated sulfuric acid was added little by little. Subsequently, 15.12 g (100 mmol) of 3-(3-pyridil)propipnc acid was added little by little with stirring, and the mixture was heated up to 120 degrees C. under stirring over 5 hours. After cooling to room temperature, 4N sodium hydroxide solution was added with stirring until the pH reached 7. The organic matter was extracted by adding 250 mL of ethyl acetate, followed by rinsing with 300 mL of water and being dried on magnesium sulfate. The solvent was distilled away, and the residue was purified by column chromatography on silica gel using a mixture of hexane (available from Kanto Chemical Co., Inc.) and ethyl acetate (available from Kanto Chemical Co., Inc.) (volume ratio ranging from 5:5 to 0:10) as the eluent to obtain 15.88 g of Intermediate 5.

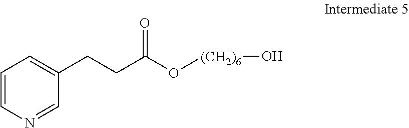

Then 12.57 g (50 mmol) of Intermediate 5 was dissolved in 20 mL of dehydrated THF. To the resulting solution, a solution containing 8.47 g (60 mmol) of acrylic acid 2-isocyanatoethyl ester dissolved in 10 mL of dehydrated THE was added dropwise over 10 minutes, followed by stirring at 35 degrees C. for 12 hours. The resulting reaction solution was stripped of the solvent, and the residue was purified by column chromatography on silica gel using a mixture of hexane/ethyl acetate (volume ratio ranging from 5:5 to 0:10) as the eluent to obtain 14.62 g of Monomer M-7.

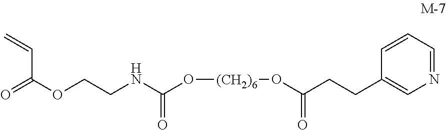

### Synthesis Example 8

### Synthesis of Monomer M-8

A total of 6.68 g (50 mmol) of 4-pyridine propanol (available from Tokyo Chemical Industry Co., Ltd.) was dissolved in 10 mL of dehydrated THF. To the resulting solution, a solution containing 8.47 g (60 mmol) of acrylic acid 2-isocyanatoethyl ester dissolved in 10 mL of dehydrated THF was added dropwise over 10 minutes, followed by stirring at 35 degrees C. for 12 hours. The resulting reaction solution was stripped of the solvent, and the residue was purified by column chromatography on silica gel using a mixture of hexane/ethyl acetate (volume ratio ranging from 5:5 to 0:10) as the eluent to obtain 9.87 g of Monomer M-8.

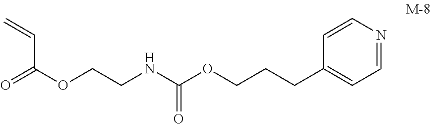 [SMILES: C=CC(=O)OCCNC(=O)OCCCc1ccncc1]

### Synthesis Example 9

### Synthesis of Monomer M-9

A total of 5.41 g (50 mmol) of 4-(aminomethyl)pyridine (available from Tokyo Chemical Industry Co., Ltd.) was dissolved in 10 mL of dehydrated THF. To the resulting solution, a solution containing 8.47 g (60 mmol) of acrylic acid 2-isocyanatoethyl ester dissolved in 10 mL of dehydrated THE was added dropwise over 10 minutes, followed by stirring at 35 degrees C. for 12 hours. The resulting reaction solution was stripped of the solvent, and the residue was purified by column chromatography on silica gel using a mixture of hexane/ethyl acetate (volume ratio ranging from 5:5 to 0:10) as the eluent to obtain 8.91 g of Monomer M-9.

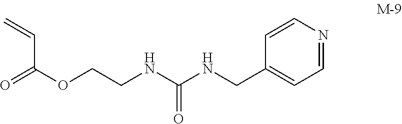 [SMILES: C=CC(=O)OCCNC(=O)NCc1ccncc1]

### Synthesis Example 10

### Synthesis of Monomer M-10

A total of 6.11 g (50 mmol) of 4-(2-aminoethyl)pyridine (available from Tokyo Chemical Industry Co., Ltd.) was dissolved in 10 mL of dehydrated THF. To the resulting solution, a solution containing 8.47 g (60 mmol) of acrylic acid 2-isocyanatoethyl ester dissolved in 10 mL of dehydrated THE was added dropwise over 10 minutes, followed by stirring at 35 degrees C. for 12 hours. The resulting reaction solution was stripped of the solvent, and the residue was purified by column chromatography on silica gel using a mixture of hexane/ethyl acetate (volume ratio ranging from 5:5 to 0:10) as the eluent to obtain 9.87 g of Monomer M-10.

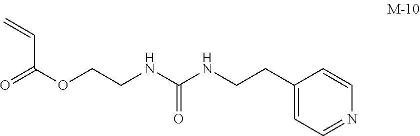 [SMILES: C=CC(=O)OCCNC(=O)NCCc1ccncc1]

### Synthesis Example 11

### Synthesis of Monomer M-11

A total of 11.16 g (50 mmol) of Intermediate 2 was dissolved in 20 mL of dehydrated THF. To the resulting solution, a solution containing 9.25 g (60 mmol) of N-(3-isocyanatopropyl)acrylamide (available from Chemieliva Pharmaceutical Co., Ltd.) dissolved in 10 mL of dehydrated THF was added dropwise over 10 minutes, followed by stirring at 35 degrees C. for 12 hours. The resulting reaction solution was stripped of the solvent, and the residue was purified by column chromatography on silica gel using a mixture of hexane/ethyl acetate (volume ratio ranging from 5:5 to 0:10) as the eluent to obtain 14.22 g of Monomer M-11.

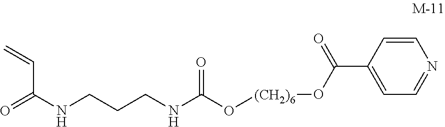

### Synthesis Example 12

### Synthesis of Monomer M-12

A total of 9.76 g (50 mmol) of Intermediate 4 was dissolved in 20 mL of dehydrated THF. To the resulting solution, a solution containing 9.25 g (60 mmol) of N-(3-isocyanatopropyl)acrylamide dissolved in 10 mL of dehydrated THE was added dropwise over 10 minutes, followed by stirring at 35 degrees C. for 12 hours. The resulting reaction solution was stripped of the solvent, and the residue was purified by column chromatography on silica gel using a mixture of hexane/ethyl acetate (volume ratio ranging from 5:5 to 0:10) as the eluent to obtain 12.80 g of Monomer M-12.

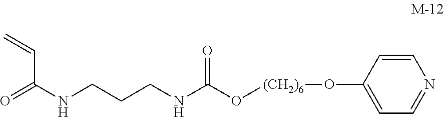

### Synthesis Example 13

### Synthesis of Monomer M-13

A total of 12.57 g (50 mmol) of Intermediate 5 was dissolved in 20 mL of dehydrated THF. To the resulting solution, a solution containing 9.25 g (60 mmol) of N-(3-isocyanatopropyl)acrylamide dissolved in 10 mL of dehydrated THE was added dropwise over 10 minutes, followed by stirring at 35 degrees C. for 12 hours. The resulting reaction solution was stripped of the solvent, and the residue was purified by column chromatography on silica gel using a mixture of hexane/ethyl acetate (volume ratio ranging from 5:5 to 0:10) as the eluent to obtain 15.22 g of Monomer M-13.

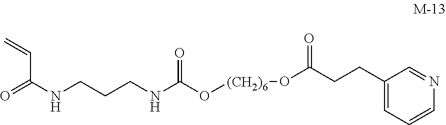

### Synthesis Example 14

### Synthesis of Monomer M-14

A total of 6.86 g (50 mmol) of 4-pyridine propanol was dissolved in 10 mL of dehydrated THF. To the resulting solution, a solution containing 9.25 g (60 mmol) of N-(3-isocyanatopropyl)acrylamide dissolved in 10 mL of dehydrated THE was added dropwise over 10 minutes, followed by stirring at 35 degrees C. for 12 hours. The resulting reaction solution was stripped of the solvent, and the residue was purified by column chromatography on silica gel using a mixture of hexane/ethyl acetate (volume ratio ranging from 5:5 to 0:10) as the eluent to obtain 10.89 g of Monomer M-14.

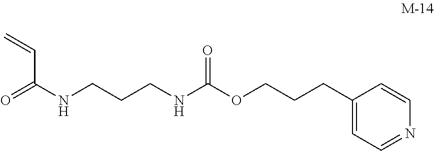 [SMILES: C=CC(=O)NCCCNC(=O)OCCCc1ccncc1]

### Synthesis Example 15

### Synthesis of Monomer M-15

A total of 5.41 g (50 mmol) of 4-(aminomethyl)pyridine was dissolved in 10 mL of dehydrated THF. To the resulting solution, a solution containing 9.25 g (60 mmol) of N-(3-isocyanatopropyl)acrylamide dissolved in 10 mL of dehydrated THE was added dropwise over 10 minutes, followed by stirring at 35 degrees C. for 12 hours. The resulting reaction solution was stripped of the solvent, and the residue was purified by column chromatography on silica gel using a mixture of hexane/ethyl acetate (volume ratio ranging from 5:5 to 0:10) as the eluent to obtain 9.87 g of Monomer M-15.

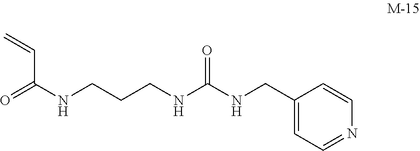 [SMILES: C=CC(=O)NCCCNC(=O)NCc1ccncc1]

### Synthesis Example 16

### Synthesis of Monomer M-16

A total of 11.16 g (50 mmol) of Intermediate 2 was dissolved in 20 mL of dehydrated THF. To the resulting solution, a solution containing 11.95 g (60 mmol) of methacrylic acid 2-(2-isocyanatohexyl ethylester (available from Chemieliva Pharmaceutical Co., Ltd.) dissolved in 10 mL of dehydrated THE was added dropwise over 10 minutes, followed by stirring at 35 degrees C. for 12 hours. The resulting reaction solution was stripped of the solvent, and the residue was purified by column chromatography on silica gel using a mixture of hexane/ethyl acetate (volume ratio ranging from 5:5 to 0:10) as the eluent to obtain 15.44 g of Monomer M-16.

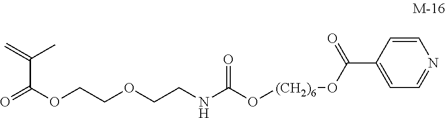

### Synthesis Example 17

### Synthesis of Monomer M-17

A total of 9.76 g (50 mmol) of Intermediate 4 was dissolved in 20 mL of dehydrated THF. To the resulting solution, a solution containing 11.95 g (60 mmol) of methacrylic acid 2-(2-isocyanatohexyl ethylester dissolved in 10 mL of dehydrated THE was added dropwise over 10 minutes, followed by stirring at 35 degrees C. for 12 hours. The resulting reaction solution was stripped of the solvent, and the residue was purified by column chromatography on silica gel using a mixture of hexane/ethyl acetate (volume ratio ranging from 5:5 to 0:10) as the eluent to obtain 14.18 g of Monomer M-17.

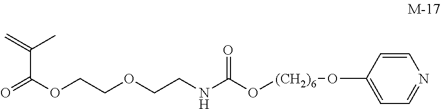

### Synthesis Example 18

### Synthesis of Monomer M-18

A total of 12.57 g (50 mmol) of Intermediate 5 was dissolved in 20 mL of dehydrated THF. To the resulting solution, a solution containing 11.95 g (60 mmol) of methacrylic acid 2-(2-isocyanatohexyl ethylester dissolved in 10 mL of dehydrated THE was added dropwise over 10 minutes, followed by stirring at 35 degrees C. for 12 hours. The resulting reaction solution was stripped of the solvent, and the residue was purified by column chromatography on silica gel using a mixture of hexane/ethyl acetate (volume ratio ranging from 5:5 to 0:10) as the eluent to obtain 16.45 g of Monomer M-18.

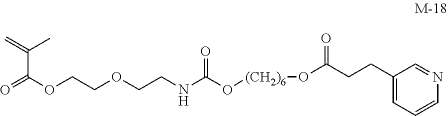

### Synthesis Example 19

### Synthesis of Monomer M-19

A total of 6.86 g (50 mmol) of 4-pyridine propanol was dissolved in 10 mL of dehydrated THF. To the resulting solution, a solution containing 11.95 g (60 mmol) of methacrylic acid 2-(2-isocyanatohexyl ethylester dissolved in 10 mL of dehydrated THE was added dropwise over 10 minutes, followed by stirring at 35 degrees C. for 12 hours. The resulting reaction solution was stripped of the solvent, and the residue was purified by column chromatography on silica gel using a mixture of hexane/ethyl acetate (volume ratio ranging from 5:5 to 0:10) as the eluent to obtain 12.45 g of Monomer M-19.

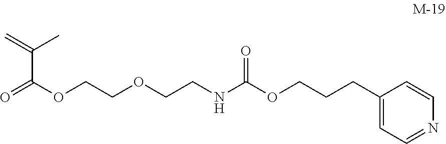 [SMILES: C=C(C)C(=O)OCCOCCNC(=O)OCCCc1ccncc1]

### Synthesis Example 20

### Synthesis of Monomer M-20

A total of 5.41 g (50 mmol) of 4-(2-aminomethyl)pyridine was dissolved in 10 mL of dehydrated THF. To the resulting solution, a solution containing 11.95 g (60 mmol) of methacrylic acid 2-(2-isocyanatohexyl ethylester dissolved in 10 mL of dehydrated THE was added dropwise over 10 minutes, followed by stirring at 35 degrees C. for 12 hours. The resulting reaction solution was stripped of the solvent, and the residue was purified by column chromatography on silica gel using a mixture of hexane/ethyl acetate (volume ratio ranging from 5:5 to 0:10) as the eluent to obtain 11.35 g of Monomer M-20.

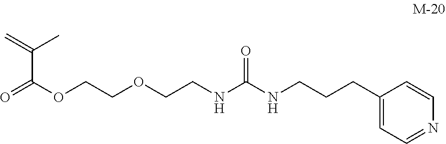 [SMILES: C=C(C)C(=O)OCCOCCNC(=O)NCCCc1ccncc1]

The structures of the monomers of Monomer M-1 to M-20 obtained in Synthesis Examples 1 to 20 of Monomer are shown in Tables 1 and 2 below.

TABLE 1

| Synthesis | | | | |
|---|---|---|---|---|
| Example | Monomer | R₁ | L₁ | X |
| 1 | M-1 | —CH₃ | —COO— | —(CH₂)₂— |
| 2 | M-2 | —CH₃ | —COO— | —(CH₂)₂— |
| 3 | M-3 | —CH₃ | —COO— | —(CH₂)₆— |
| 4 | M-4 | —CH₃ | —COO— | —(CH₂)₂(CH(CH₃))(CH₂)₃(C(CH₃)₂)— |
| 5 | M-5 | —CH₃ | —COO— | —(CH₂)₂— |
| 6 | M-6 | —H | —COO— | —(CH₂)₂— |
| 7 | M-7 | —H | —COO— | —(CH₂)₂— |
| 8 | M-8 | —H | —COO— | —(CH₂)₂— |
| 9 | M-9 | —H | —COO— | —(CH₂)₂— |
| 10 | M-10 | —H | —COO— | —(CH₂)₂— |
| 11 | M-11 | —H | —CONH— | —(CH₂)₃— |
| 12 | M-12 | —H | —CONH— | —(CH₂)₃— |
| 13 | M-13 | —H | —CONH— | —(CH₂)₃— |
| 14 | M-14 | —H | —CONH— | —(CH₂)₃— |
| 15 | M-15 | —H | —CONH— | —(CH₂)₃— |
| 16 | M-16 | —CH₃ | —COO— | —(CH₂)₂—O—(CH₂)₂— |
| 17 | M-17 | —CH₃ | —COO— | —(CH₂)₂—O—(CH₂)₂— |
| 18 | M-18 | —CH₃ | —COO— | —(CH₂)₂—O—(CH₂)₂— |
| 19 | M-19 | —CH₃ | —COO— | —(CH₂)₂—O—(CH₂)₂— |
| 20 | M-20 | —CH₃ | —COO— | —(CH₂)₂—O—(CH₂)₂— |

| Synthesis | | | | |
|---|---|---|---|---|
| Example | Monomer | L₂ | Y | L₃ |
| 1 | M-1 | —O— | —(CH₂)₂— | —OCO— |
| 2 | M-2 | —O— | —(CH₂)₆— | —OCO— |
| 3 | M-3 | —O— | —(CH₂)₆— | —OCO— |
| 4 | M-4 | —O— | —(CH₂)₆— | —OCO— |
| 5 | M-5 | —O— | —(CH₂)₁₀— | —OCO— |
| 6 | M-6 | —O— | —(CH₂)₆— | —O— |
| 7 | M-7 | —O— | —(CH₂)₆— | —OCO—(CH₂)₂— |
| 8 | M-8 | —O— | — | —(CH₂)₃— |
| 9 | M-9 | —NH— | — | —(CH₂)— |
| 10 | M-10 | —NH— | — | —(CH₂)₂— |
| 11 | M-11 | —O— | —(CH₂)₆— | —OCO— |
| 12 | M-12 | —O— | —(CH₂)₆— | —O— |
| 13 | M-13 | —O— | —(CH₂)₆— | —OCO—(CH₂)₂— |
| 14 | M-14 | —O— | — | —(CH₂)₃— |
| 15 | M-15 | —NH— | — | —(CH₂)— |
| 16 | M-16 | —O— | —(CH₂)₆— | —OCO— |
| 17 | M-17 | —O— | —(CH₂)₆— | —O— |
| 18 | M-18 | —O— | —(CH₂)₆— | —OCO—(CH₂)₂— |
| 19 | M-19 | —O— | — | —(CH₂)₃— |
| 20 | M-20 | —NH— | — | —(CH₂)— |

TABLE 2

| Synthesis | | | | |
|---|---|---|---|---|
| Example | Monomer | L₂ | Y | L₃ |
| 1 | M-1 | —O— | —(CH₂)₂— | —OCO— |
| 2 | M-2 | —O— | —(CH₂)₆— | —OCO— |
| 3 | M-3 | —O— | —(CH₂)₆— | —OCO— |
| 4 | M-4 | —O— | —(CH₂)₆— | —OCO— |
| 5 | M-5 | —O— | —(CH₂)₁₀— | —OCO— |
| 6 | M-6 | —O— | —(CH₂)₆— | —O— |
| 7 | M-7 | —O— | —(CH₂)₆— | —OCO—(CH₂)₂— |
| 8 | M-8 | —O— | — | —(CH₂)₃— |
| 9 | M-9 | —NH— | — | —(CH₂)— |
| 10 | M-10 | —NH— | — | —(CH₂)₂— |
| 11 | M-11 | —O— | —(CH₂)₆— | —OCO— |
| 12 | M-12 | —O— | —(CH₂)₆— | —O— |
| 13 | M-13 | —O— | —(CH₂)₆— | —OCO—(CH₂)₂— |
| 14 | M-14 | —O— | — | —(CH₂)₃— |
| 15 | M-15 | —NH— | — | —(CH₂)— |
| 16 | M-16 | —O— | —(CH₂)₆— | —OCO— |
| 17 | M-17 | —O— | —(CH₂)₆— | —O— |
| 18 | M-18 | —O— | —(CH₂)₆— | —OCO—(CH₂)₂— |
| 19 | M-19 | —O— | — | —(CH₂)₃— |
| 20 | M-20 | —NH— | — | —(CH₂)— |

### Comparative Synthesis Example 1

### Synthesis of Comparative Monomer RM-1

A total of 13.01 g (100 mmol) of 2-hydroxyethyl methacrylate was dissolved in 50 mL of dimethylacetamide (available from Kanto Chemical Co., Inc.), and then 16.81 g (100 mmol) of hexamethylene diisocyanate was added dropwise over 30 minutes, followed by stirring at room temperature for 4 hours. Subsequently, a solution of 12.31 g (100 mmol) of 2-(2-hydroxyethyl)pyridine in 20 mL of dimethylacetamide was added, and the mixture was stirred at room temperature for 4 hours. To the resulting reaction solution, 300 mL of water was added, and the mixture was extracted twice with 200 mL of ethyl acetate. The organic phase isolated was dried over magnesium sulfate and the solvent was removed. The residue was purified by column chromatography on silica gel using a mixture of hexane/ethyl acetate (volume ratio ranging from 4:6 to 0:10) as the eluent, yielding 22.73 g of Comparative Monomer RM-1.

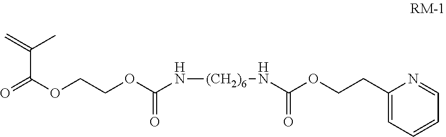

### Comparative Synthesis Example 2

### Synthesis of Comparative Monomer RM-2

A total of 59.08 g (500 mmol) of 1,6-hexane diol was heated up to 80 degrees C., and then 1.96 g (20 mmol) of concentrated sulfuric acid was added little by little. Subsequently, 12.22 g (100 mmol) of isonicotinic acid was added little by little during stirring, and the mixture was heated up to 120 degrees C. under stirring over 5 hours. After cooling to room temperature, 4N sodium hydroxide solution was added with stirring until the pH reached 7. The mixture was extracted twice with 200 ml of ethyl acetate, and the organic phase obtained was washed twice with 200 ml of water. The isolated organic phase was then dried over magnesium sulfate. The solvent was distilled away from the organic phase, and the residue was purified by column chromatography on silica gel using a mixture of hexane (available from Kanto Chemical Co., Inc.) and ethyl acetate (available from Kanto Chemical Co., Inc.) (volume ratio ranging from 5:5 to 0:10) as the eluent to obtain 13.81 g of benzoic acid 6-hydroxy hexyl ester.

Next, 11.12 g (50 mmol) of benzoi acid 6-hydroxy hexyl ester was dissolved in 20 mL of dried THF. To the resulting solution, a solution containing 9.31 g (60 mmol) of methacrylic acid 2-isocyanatoethyl dissolved in 10 mL of dehydrated THF was added dropwise over 10 minutes, followed by stirring at room temperature for 12 hours. The resulting reaction solution was stripped of the solvent, and the residue was purified by column chromatography on silica gel using a mixture of hexane/ethyl acetate (volume ratio ranging from 5:5 to 1:9) as the eluent to obtain 14.38 g of Comparative Monomer RM-2.

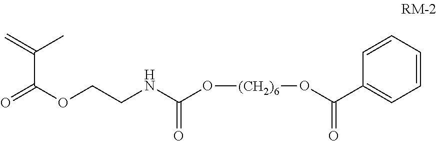

### Example 1

### Synthesis of Copolymer CP-1

A total of 25.0 parts by mass of acrylic acid (AA, available from Tokyo Chemical Industry Co., Ltd.), 75.0 parts by mass of monomer M-1, and 0.95 parts by mass of 2,2′-azoiso(butyronitrile) (AIBN, available from Tokyo Chemical Industry Co., Ltd.) were dissolved in 252 parts by mass of dimethylformamide (DMF) (available from Kanto Chemical Co., Inc.). This solution was added dropwise over 1 hour to 28 parts by mass of DMF heated to 80 degrees C. in a nitrogen atmosphere, and stirred at 80 degrees C. for 5 hours. After cooling to room temperature, the resulting reaction solution was poured into 500 mL of water. The precipitate was separated by filtration and then dried under a reduced pressure to obtain 97.7 parts by mass of copolymer CP-1 (weight-average molecular weight Mw of 17,800).

### Example 2

### Synthesis of Copolymer CP-2

A total of 98.1 parts by mass of Copolymer CP-2 (with a Mw of 23,300) was obtained in the same manner as in Example 1 except that 20.0 parts by mass of acrylic acid, 80.0 parts by mass of monomer M-2, and 0.72 parts by mass of 2,2′-azoiso(butyronitrile) were used.

### Example 3

### Synthesis of Copolymer CP-3

A total of 97.2 parts by mass of Copolymer CP-3 (with a Mw of 29,200) was obtained in the same manner as in Example 1 except that 15.0 parts by mass of acrylic acid, 85.0 parts by mass of monomer M-3, and 0.54 parts by mass of 2,2′-azoiso(butyronitrile) were used.

### Example 4

### Synthesis of Copolymer CP-4

A total of 97.9 parts by mass of Copolymer CP-4 (with a Mw of 35,700) was obtained in the same manner as in Example 1 except that 10.0 parts by mass of acrylic acid, 90.0 parts by mass of monomer M-4, and 0.37 parts by mass of 2,2′-azoiso(butyronitrile) were used.

### Example 5

### Synthesis of Copolymer CP-5

A total of 98.2 parts by mass of Copolymer CP-5 (with a Mw of 47,100) was obtained in the same manner as in Example 1 except that 5.0 parts by mass of acrylic acid, 95.0 parts by mass of monomer M-5, and 0.24 parts by mass of 2,2′-azoiso(butyronitrile) were used.

### Example 6

### Synthesis of Copolymer CP-6

A total of 20.0 parts by mass of acrylic acid, 80.0 parts by mass of Monomer M-2, and 0.20 parts by mass of 2,2′-azoiso(butyronitrile) were dissolved in 216 parts by mass of DMF. This solution was added dropwise over 1 hour to 24 parts by mass of DMF heated to 80 degrees C. in a nitrogen atmosphere, and stirred at 80 degrees C. for 5 hours. After cooling to room temperature, the resulting reaction solution was poured into 500 mL of water. The precipitate was filtered followed by drying with a reduced pressure to obtain 97.1 parts by mass of Copolymer CP-6 (Mw: 51,300).

### Example 7

### Synthesis of Copolymer CP-7

A total of 20.0 parts by mass of acrylic acid, 80.0 parts by mass of Monomer M-2, 1.61 parts by mass of 2,2′-azoiso(butyronitrile), and 0.26 parts by mass of 3-mercaptopropionic acid (3MPA, available from Tokyo Chemical Industry Co., Ltd.) were dissolved in 252 parts by mass of DMF. This solution was added dropwise over 1 hour to 28 parts by mass of DMF heated to 80 degrees C. in a nitrogen atmosphere, and stirred at 80 degrees C. for 5 hours. After cooling to room temperature, the resulting reaction solution was poured into 500 mL of water. The precipitate was filtered followed by drying with a reduced pressure to obtain 97.0 parts by mass of Copolymer CP-7 (Mw: 4,100).

### Example 8

### Synthesis of Copolymer CP-8

A total of 20.0 parts by mass of 2-acrylamido-2-methylpropanesulfonic acid (AAMS, available from Tokyo Chemical Industry Co., Ltd.), 80.0 parts by mass of Monomer M-2, and 0.25 parts by mass of 2,2′-azoiso(butyronitrile) were dissolved in 252 parts by mass of DMF. This solution was added dropwise over 1 hour to 28 parts by mass of DMF heated to 80 degrees C. in a nitrogen atmosphere, and stirred at 80 degrees C. for 5 hours. After cooling to room temperature, the resulting reaction solution was poured into 500 mL of water. The precipitate was filtered followed by drying with a reduced pressure to obtain 98.5 parts by mass of Copolymer CP-8 (Mw: 41,600).

### Example 9

### Synthesis of Copolymer CP-9

A total of 20.0 parts by mass of 2-acrylamido-2-methylpropanesulfonic acid, 80.0 parts by mass of Monomer M-2, and 0.13 parts by mass of 2,2′-azoiso(butyronitrile) were dissolved in 216 parts by mass of DMF. This solution was added dropwise over 1 hour to 24 parts by mass of DMF heated to 80 degrees C. in a nitrogen atmosphere, and stirred at 80 degrees C. for 5 hours. After cooling to room temperature, the resulting reaction solution was poured into 500 mL of water. The precipitate was filtered followed by drying with a reduced pressure to obtain 97.0 parts by mass of Copolymer CP-9 (Mw: 52,200).

### Example 10

### Synthesis of Copolymer CP-10

A total of 20.0 parts by mass of 2-acrylamido-2-methylpropanesulfonic acid, 80.0 parts by mass of Monomer M-2, 1.01 parts by mass of 2,2′-azoiso(butyronitrile), and 0.16 parts by mass of 3-mercapto propionic acid were dissolved in 252 parts by mass of DMF. This solution was added dropwise over 1 hour to 28 parts by mass of DMF heated to 80 degrees C. in a nitrogen atmosphere, and stirred at 80 degrees C. for 5 hours. After cooling to room temperature, the resulting reaction solution was poured into 500 mL of water. The precipitate was filtered followed by drying with a reduced pressure to obtain 97.0 parts by mass of Copolymer CP-10 (Mw: 4,300).

### Example 11

### Synthesis of Copolymer CP-11

A total of 98.2 parts by mass of Copolymer CP-11 (with a Mw of 18,100) was obtained in the same manner as in Example 1 except that 25.0 parts by mass of acrylic acid, 75.0 parts by mass of Monomer M-6, and 0.88 parts by mass of 2,2′-azoiso(butyronitrile) were used.

### Example 12

### Synthesis of Copolymer CP-12

A total of 98.4 parts by mass of Copolymer CP-12 (with a Mw of 24,600) was obtained in the same manner as in Example 1 except that 20.0 parts by mass of acrylic acid, 80.0 parts by mass of Monomer M-7, and 0.71 parts by mass of 2,2′-azoiso(butyronitrile) were used.

### Example 13

### Synthesis of Copolymer CP-13

A total of 98.5 parts by mass of Copolymer CP-13 (with a Mw of 30,100) was obtained in the same manner as in Example 1 except that 15.0 parts by mass of acrylic acid, 85.0 parts by mass of Monomer M-8, and 0.67 parts by mass of 2,2′-azoiso(butyronitrile) were used.

### Example 14

### Synthesis of Copolymer CP-14

A total of 98.0 parts by mass of Copolymer CP-14 (with a Mw of 36,200) was obtained in the same manner as in Example 1 except that 10.0 parts by mass of acrylic acid, 90.0 parts by mass of Monomer M-9, and 0.57 parts by mass of 2,2′-azoiso(butyronitrile) were used.

### Example 15

### Synthesis of Copolymer CP-15

A total of 98.5 parts by mass of Copolymer CP-15 (with a Mw of 46,900) was obtained in the same manner as in Example 1 except that 5.0 parts by mass of acrylic acid, 95.0 parts by mass of Monomer M-10, and 0.35 parts by mass of 2,2′-azoiso(butyronitrile) were used.

### Example 16

### Synthesis of Copolymer CP-16

A total of 98.5 parts by mass of Copolymer CP-16 (with a Mw of 53,400) was obtained in the same manner as in Example 6 except that 20.0 parts by mass of acrylic acid, 80.0 parts by mass of Monomer M-8, and 0.28 parts by mass of 2,2′-azoiso(butyronitrile) were used.

### Example 17

### Synthesis of Copolymer CP-17

A total of 98.0 parts by mass of Copolymer CP-17 (with a Mw of 4,100) was obtained in the same manner as in Example 7 except that 20.0 parts by mass of acrylic acid, 80.0 parts by mass of Monomer M-8, 1.86 parts by mass of 2,2′-azoisobutyronitrile, and 0.30 parts by mass of 3-mercapto propionic acid were used.

### Example 18

### Synthesis of Copolymer CP-18

A total of 98.8 parts by mass of Copolymer CP-18 (with a Mw of 42,600) was obtained in the same manner as in Example 8 except that 20.0 parts by mass of 2-acrylic amide-2-methylpropane sulfonic acid 80.0 parts by mass of Monomer M-8, and 0.32 parts by mass of 2,2′-azoiso(butyronitrile) were used.

### Example 19

### Synthesis of Copolymer CP-19

A total of 98.0 parts by mass of Copolymer CP-19 (with a Mw of 52,800) was obtained in the same manner as in Example 9 except that 20.0 parts by mass of 2-acrylic amide-2-methylpropane sulfonic acid 80.0 parts by mass of monomer M-8, and 0.16 parts by mass of 2,2′-azoiso(butyronitrile) were used.

### Example 20

### Synthesis of Copolymer CP-20

A total of 98.7 parts by mass of Copolymer CP-20 (with a Mw of 4,500) was obtained in the same manner as in Example 10 except that 20.0 parts by mass of 2-acrylic amide-2-methylpropane sulfonic acid 80.0 parts by mass of Monomer M-8, 1.26 parts by mass of 2,2′-azoiso(butyronitrile), and 0.20 pars of 3-mercapto propionic acid were used.

### Example 21

### Synthesis of Copolymer CP-21

A total of 98.4 parts by mass of Copolymer CP-21 (with a Mw of 19,700) was obtained in the same manner as in Example 1 except that 25.0 parts by mass of acrylic acid, 75.0 parts by mass of Monomer M-11, and 0.90 parts by mass of 2,2′-azoiso(butyronitrile) were used.

### Example 22

### Synthesis of Copolymer CP-22

A total of 98.8 parts by mass of Copolymer CP-22 (with a Mw of 23,900) was obtained in the same manner as in Example 1 except that 20.0 parts by mass of acrylic acid, 80.0 parts by mass of Monomer M-12, and 0.75 parts by mass of 2,2′-azoiso(butyronitrile) were used.

### Example 23

### Synthesis of Copolymer CP-23

A total of 98.1 parts by mass of Copolymer CP-23 (with a Mw of 29,800) was obtained in the same manner as in Example 1 except that 15.0 parts by mass of acrylic acid, 85.0 parts by mass of Monomer M-13, and 0.55 parts by mass of 2,2′-azoiso(butyronitrile) were used.

### Example 24

### Synthesis of Copolymer CP-24

A total of 98.6 parts by mass of Copolymer CP-24 (with a Mw of 35,100) was obtained in the same manner as in Example 1 except that 10.0 parts by mass of acrylic acid, 90.0 parts by mass of Monomer M-14, and 0.51 parts by mass of 2,2′-azoiso(butyronitrile) were used.

### Example 25

### Synthesis of Copolymer CP-25

A total of 98.0 parts by mass of Copolymer CP-25 (with a Mw of 43,800) was obtained in the same manner as in Example 1 except that 5.0 parts by mass of acrylic acid, 95.0 parts by mass of Monomer M-15, and 0.35 parts by mass of 2,2′-azoiso(butyronitrile) were used.

### Example 26

### Synthesis of Copolymer CP-26

A total of 97.7 parts by mass of Copolymer CP-26 (with a Mw of 54,100) was obtained in the same manner as in Example 6 except that 20.0 parts by mass of acrylic acid, 80.0 parts by mass of Monomer M-12, and 0.21 parts by mass of 2,2′-azoiso(butyronitrile) were used.

### Example 27

### Synthesis of Copolymer CP-27

A total of 98.4 parts by mass of Copolymer CP-27 (with a Mw of 4,600) was obtained in the same manner as in Example 7 except that 20.0 parts by mass of acrylic acid, 80.0 parts by mass of Monomer M-12, 1.68 parts by mass of 2,2′-azoisobutyronitrile, and 0.27 parts by mass of 3-mercapto propionic acid were used.

### Example 28

### Synthesis of Copolymer CP-28

A total of 98.0 parts by mass of Copolymer CP-28 (with a Mw of 40,900) was obtained in the same manner as in Example 8 except that 20.0 parts by mass of 2-acrylic amide-2-methylpropane sulfonic acid 80.0 parts by mass of Monomer M-12, and 0.27 parts by mass of 2,2′-azoiso(butyronitrile) were used.

### Example 29

### Synthesis of Copolymer CP-29

A total of 98.6 parts by mass of Copolymer CP-29 (with a Mw of 56,200) was obtained in the same manner as in Example 9 except that 20.0 parts by mass of 2-acrylic amide-2-methylpropane sulfonic acid 80.0 parts by mass of Monomer M-12, and 0.13 parts by mass of 2,2′-azoiso(butyronitrile) were used.

### Example 30

### Synthesis of Copolymer CP-30

A total of 97.7 parts by mass of Copolymer CP-30 (with a Mw of 4,700) was obtained in the same manner as in Example 10 except that 20.0 parts by mass of 2-acrylic amide-2-methylpropane sulfonic acid 80.0 parts by mass of Monomer M-12, 1.68 parts by mass of 2,2′-azoiso(butyronitrile), and 0.17 pars of 3-mercapto propionic acid were used.

### Example 31

### Synthesis of Copolymer CP-31

A total of 25.0 parts by mass of methacrylic acid (MA, available from Tokyo Chemical Industry Co. Ltd.), 75.0 parts by mass of Monomer M-16, and 0.77 parts by mass of 2,2′-azoiso(butyronitrile) were dissolved in 252 parts by mass of DMF. This solution was added dropwise over 1 hour to 28 parts by mass of DMF heated to 80 degrees C. in a nitrogen atmosphere, and stirred at 80 degrees C. for 5 hours. After cooling to room temperature, the resulting reaction solution was poured into 500 mL of water. The precipitate was filtered followed by drying with a reduced pressure to obtain 98.2 parts by mass of Copolymer CP-31 (Mw: 18,800).

### Example 32

### Synthesis of Copolymer CP-32

A total of 98.1 parts by mass of Copolymer CP-32 (with a Mw of 23,000) was obtained in the same manner as in Example 31 except that 20.0 parts by mass of methacrylic acid, 80.0 parts by mass of Monomer M-17, and 0.64 parts by mass of 2,2′-azoiso(butyronitrile) were used.

### Example 33

### Synthesis of Copolymer CP-33

A total of 98.9 parts by mass of Copolymer CP-33 (with a Mw of 30,100) was obtained in the same manner as in Example 31 except that 15.0 parts by mass of methacrylic acid, 85.0 parts by mass of Monomer M-18, and 0.48 parts by mass of 2,2′-azoiso(butyronitrile) were used.

### Example 34

### Synthesis of Copolymer CP-34

A total of 98.2 parts by mass of Copolymer CP-34 (with a Mw of 35,900) was obtained in the same manner as in Example 31 except that 10.0 parts by mass of methacrylic acid, 90.0 parts by mass of Monomer M-19, and 0.44 parts by mass of 2,2′-azoiso(butyronitrile) were used.

### Example 35

### Synthesis of Copolymer CP-35

A total of 98.9 parts by mass of Copolymer CP-35 (with a Mw of 45,700) was obtained in the same manner as in Example 31 except that 5.0 parts by mass of methacrylic acid, 95.0 parts by mass of Monomer M-20, and 0.30 parts by mass of 2,2′-azoiso(butyronitrile) were used.

### Example 36

### Synthesis of Copolymer CP-36

A total of 20.0 parts by mass of methacrylic acid, 70.0 parts by mass of Monomer M-3, 10.0 parts by mass of styrene (St, available from Tokyo Chemical Industry Co., Ltd.) and 0.49 parts by mass of 2,2′-azoiso(butyronitrile) were dissolved in 252 parts by mass of DMF. This solution was added dropwise over 1 hour to 28 parts by mass of DMF heated to 80 degrees C. in a nitrogen atmosphere, and stirred at 80 degrees C. for 5 hours. After cooling to room temperature, the resulting reaction solution was poured into 500 mL of water. The precipitate was filtered followed by drying with a reduced pressure to obtain 98.3 parts by mass of Copolymer CP-36 (Mw: 37,900).

### Example 37

### Synthesis of Copolymer CP-37

A total of 20.0 parts by mass of methacrylic acid, 70.0 parts by mass of Monomer M-3, 10.0 parts of dodecyl methacrylic acid (DdMA, available from Tokyo Chemical Industry Co., Ltd.) and 0.43 parts by mass of 2,2′-azoiso(butyronitrile) were dissolved in 252 parts by mass of DMF. This solution was added dropwise over 1 hour to 28 parts by mass of DMF heated to 80 degrees C. in a nitrogen atmosphere, and stirred at 80 degrees C. for 5 hours. After cooling to room temperature, the resulting reaction solution was poured into 500 mL of water. The precipitate was filtered followed by drying with a reduced pressure to obtain 98.6 parts by mass of Copolymer CP-37 (Mw: 38,600).

### Example 38

### Synthesis of Copolymer CP-38

A total of 20.0 parts by mass of 2-acrylamido-2-methylpropanesulfonic acid, 70.0 parts by mass of Monomer M-3, 10.0 parts by mass of styrene, and 0.35 parts by mass of 2,2′-azoiso(butyronitrile) were dissolved in 252 parts by mass of DMF. This solution was added dropwise over 1 hour to 28 parts by mass of DMF heated to 80 degrees C. in a nitrogen atmosphere, and stirred at 80 degrees C. for 5 hours. After cooling to room temperature, the resulting reaction solution was poured into 500 mL of water. The precipitate was filtered followed by drying with a reduced pressure to obtain 98.3 parts by mass of Copolymer CP-38 (Mw: 39,900).

### Example 39

### Synthesis of Copolymer CP-39

A total of 20.0 parts by mass of 2-acrylamido-2-methylpropanesulfonic acid, 70.0 parts by mass of Monomer M-3, 10.0 parts by mass of styrene, and 0.15 parts by mass of 2,2′-azoiso(butyronitrile) were dissolved in 216 parts by mass of DMF. This solution was added dropwise over 1 hour to 24 parts by mass of DMF heated to 80 degrees C. in a nitrogen atmosphere, and stirred at 80 degrees C. for 5 hours. After cooling to room temperature, the resulting reaction solution was poured into 500 mL of water. The precipitate was filtered followed by drying with a reduced pressure to obtain 98.8 parts by mass of Copolymer CP-39 (Mw: 55,500).

### Example 40

### Synthesis of Copolymer CP-40

A total of 20.0 parts by mass of 2-acrylamiedo-2-methylpropanesulfonic acid, 70.0 parts by mass of Monomer M-3, 10.0 parts by mass of styrene, 1.18 parts by mass of 2,2′-azoiso(butyronitrile), and 0.19 parts by mass of 3-mercapto propionic acid were dissolved in 252 parts by mass of DMF. This solution was added dropwise over 1 hour to 28 parts by mass of DMF heated to 80 degrees C. in a nitrogen atmosphere, and stirred at 80 degrees C. for 5 hours. After cooling to room temperature, the resulting reaction solution was poured into 500 mL of water. The precipitate was filtered followed by drying with a reduced pressure to obtain 97.5 parts by mass of Copolymer CP-40 (Mw: 4,000).

### Comparative Example 1

### Synthesis of Comparative Copolymer RCP-1

A total of 98.5 parts by mass of Comparative Copolymer RCP-1 (with a Mw of 34,900) was obtained in the same manner as in Example 1 except that 25.0 parts by mass of acrylic acid, 75.0 parts by mass of Comparative Monomer RM-1, and 0.52 parts by mass of 2,2′-azoiso(butyronitrile) were used.

### Comparative Example 2

### Synthesis of Comparative Copolymer RCP-2

A total of 98.0 parts by mass of Comparative Copolymer RCP-2 (with a Mw of 35,300) was obtained in the same manner as in Example 1 except that 15.0 parts by mass of acrylic acid, 85.0 parts by mass of Comparative Monomer RM-1, and 0.40 parts by mass of 2,2′-azoiso(butyronitrile) were used.

### Comparative Example 3

### Synthesis of Comparative Copolymer RCP-3

A total of 97.5 parts by mass of Comparative Copolymer RCP-3 (with a Mw of 36,200) was obtained in the same manner as in Example 1 except that 5.0 parts by mass of acrylic acid, 95.0 parts by mass of Comparative Monomer RM-1, and 0.29 parts by mass of 2,2′-azoiso(butyronitrile) were used.

### Comparative Example 4

### Synthesis of Comparative Copolymer RCP-4

A total of 98.5 parts by mass of Comparative Copolymer RCP-4 (with a Mw of 36,300) was obtained in the same manner as in Example 8 except that 20.0 parts by mass of 2-acrylicamide-2-methyl propane sulfonic acid, 80.0 parts by mass of Comparative Monomer RM-1, and 0.28 parts by mass of 2,2′-azoiso(butyronitrile) were used.

### Comparative Example 5

### Synthesis of Comparative Copolymer RCP-5

A total of 98.8 parts by mass of Comparative Copolymer RCP-5 (with a Mw of 56,100) was obtained in the same manner as in Example 9 except that 20.0 parts by mass of 2-acrylicamide-2-methyl propane sulfonic acid, 80.0 parts by mass of Comparative Monomer RM-1, and 0.12 parts by mass of 2,2′-azoiso(butyronitrile) were used.

### Comparative Example 6

### Synthesis of Comparative Copolymer RCP-6

A total of 98.0 parts by mass of Comparative Copolymer RCP-6 (with a Mw of 4,600) was obtained in the same manner as in Example 10 except that 20.0 parts by mass of 2-acrylic amide-2-methylpropane sulfonic acid 80.0 parts by mass of Comparative Monomer RM-1, 0.94 parts by mass of 2,2′-azoiso(butyronitrile), and 0.15 pars of 3-mercapto propionic acid were used.

### Comparative Example 7

### Synthesis of Comparative Copolymer RCP-7

A total of 98.3 parts by mass of Comparative Copolymer RCP-7 (with a Mw of 36,900) was obtained in the same manner as in Example 36 except that 25.0 parts by mass of methacrylic acid, 70.0 parts by mass of Comparative Monomer RM-2, 5.0 parts by mass of styrene, and 0.52 parts by mass of 2,2′-azoiso(butyronitrile) were used.

### Comparative Example 8

### Synthesis of Comparative Copolymer RCP-8

A total of 98.8 parts by mass of Comparative Copolymer RCP-8 (with a Mw of 37,100) was obtained in the same manner as in Example 37 except that 5.0 parts by mass of methacrylic acid, 70.0 parts by mass of Comparative Monomer RM-2, 5.0 parts by mass of dodecyl methacrylic acid, and 0.34 parts by mass of 2,2′-azoiso(butyronitrile) were used.

### Comparative Example 9

### Synthesis of Comparative Copolymer RCP-9

A total of 98.9 parts by mass of Comparative Copolymer RCP-9 (with a Mw of 35,900) was obtained in the same manner as in Example 38 except that 20.0 parts by mass of 2-acrylicamide-2-methyl propane sulfonic acid, 70.0 parts by mass of Comparative Monomer RM-2, 10.0 parts by mass of styrene, and 0.37 parts by mass of 2,2′-azoiso(butyronitrile) were used.

### Comparative Example 10

### Synthesis of Comparative Copolymer RCP-10

A total of 98.1 parts by mass of Comparative Copolymer RCP-10 (with a Mw of 53,700) was obtained in the same manner as in Example 39 except that 20.0 parts by mass of 2-acrylicamide-2-methyl propane sulfonic acid, 70.0 parts by mass of Comparative Monomer RM-2, 10.0 parts by mass of styrene, and 0.16 parts by mass of 2,2′-azoiso(butyronitrile) were used.

### Comparative Example 11

### Synthesis of Comparative Copolymer RCP-11

A total of 97.7 parts by mass of Comparative Copolymer RCP-11 (with a Mw of 3,900) was obtained in the same manner as in Example 40 except that 20.0 parts by mass of 2-acrylic amide-2-methylpropane sulfonic acid, 70.0 parts by mass of Comparative Monomer RM-2, 10.0 parts by mass of styrene, 1.24 parts by mass of 2,2′-azoiso(butyronitrile), and 0.20 pars of 3-mercapto propionic acid were used.

The compositions, mass ratios, and weight average molecular weights Mw of Copolymers CP-1 to CP-40 synthesized in Examples 1 to 40 above, and Copolymers RCP-1 to RCP-11 synthesized in Comparative Examples to 11, are shown in Tables 3 to 4.

TABLE 3

| | | Monomer | | | | | | | |
|---|---|---|---|---|---|---|---|---|---|
| | | First | | Second | | Third | | Third | |
| | | monomer | | monomer | | monomer (1) | | monomer (2) | |
| | | | parts | | parts | | parts | | parts |
| | | | by | | by | | by | | by |
| Example | (Co)polymer | Type | mass | Type | mass | Type | mass | Type | mass |
| Example | CP-1 | M-1 | 75.0 | AA | 25.0 | — | — | — | — |
| 1 | | | | | | | | | |
| Example | CP-2 | M-2 | 80.0 | AA | 20.0 | — | — | — | — |
| 2 | | | | | | | | | |
| Example | CP-3 | M-3 | 85.0 | AA | 15.0 | — | — | — | — |
| 3 | | | | | | | | | |
| Example | CP-4 | M-4 | 90.0 | AA | 10.0 | — | — | — | — |
| 4 | | | | | | | | | |
| Example | CP-5 | M-5 | 95.0 | AA | 5.0 | — | — | — | — |
| 5 | | | | | | | | | |
| Example | CP-6 | M-2 | 80.0 | AA | 20.0 | — | — | — | — |
| 6 | | | | | | | | | |
| Example | CP-7 | M-2 | 80.0 | AA | 20.0 | — | — | — | — |
| 7 | | | | | | | | | |
| Example | CP-8 | M-2 | 80.0 | — | — | AAMS | 20.0 | — | — |
| 8 | | | | | | | | | |
| Example | CP-9 | M-2 | 80.0 | — | — | AAMS | 20.0 | — | — |
| 9 | | | | | | | | | |
| Example | CP-10 | M-2 | 80.0 | — | — | AAMS | 20.0 | — | — |
| 10 | | | | | | | | | |
| Example | CP-11 | M-6 | 75.0 | AA | 25.0 | — | — | — | — |
| 11 | | | | | | | | | |
| Example | CP-12 | M-7 | 80.0 | AA | 20.0 | — | — | — | — |
| 12 | | | | | | | | | |
| Example | CP-13 | M-8 | 85.0 | AA | 15.0 | — | — | — | — |
| 13 | | | | | | | | | |
| Example | CP-14 | M-9 | 90.0 | AA | 10.0 | — | — | — | — |
| 14 | | | | | | | | | |
| Example | CP-15 | M-10 | 95.0 | AA | 5.0 | — | — | — | — |
| 15 | | | | | | | | | |
| Example | CP-16 | M-8 | 80.0 | AA | 20.0 | — | — | — | — |
| 16 | | | | | | | | | |
| Example | CP-17 | M-8 | 80.0 | AA | 20.0 | — | — | — | — |
| 17 | | | | | | | | | |
| Example | CP-18 | M-8 | 80.0 | — | — | AAMS | 20.0 | — | — |
| 18 | | | | | | | | | |
| Example | CP-19 | M-8 | 80.0 | — | — | AAMS | 20.0 | — | — |
| 19 | | | | | | | | | |
| Example | CP-20 | M-8 | 80.0 | — | — | AAMS | 20.0 | — | — |
| 20 | | | | | | | | | |
| Example | CP-21 | M-11 | 75.0 | AA | 25.0 | — | — | — | — |
| 21 | | | | | | | | | |
| Example | CP-22 | M-12 | 80.0 | AA | 20.0 | — | — | — | — |
| 22 | | | | | | | | | |
| Example | CP-23 | M-13 | 85.0 | AA | 15.0 | — | — | — | — |
| 23 | | | | | | | | | |
| Example | CP-24 | M-14 | 90.0 | AA | 10.0 | — | — | — | — |
| 24 | | | | | | | | | |
| Example | CP-25 | M-15 | 95.0 | AA | 5.0 | — | — | — | — |
| 25 | | | | | | | | | |
| Example | CP-26 | M-12 | 80.0 | AA | 20.0 | — | — | — | — |
| 26 | | | | | | | | | |
| Example | CP-27 | M-12 | 80.0 | AA | 20.0 | — | — | — | — |
| 27 | | | | | | | | | |
| Example | CP-28 | M-12 | 80.0 | — | — | AAMS | 20.0 | — | — |
| 28 | | | | | | | | | |
| Example | CP-29 | M-12 | 80.0 | — | — | AAMS | 20.0 | — | — |
| 29 | | | | | | | | | |
| Example | CP-30 | M-12 | 80.0 | — | — | AAMS | 20.0 | — | — |
| 30 | | | | | | | | | |

| | | 3MPA | AIBN | |
|---|---|---|---|---|
| | | parts | parts | Weight average |
| | | by | by | molecular weight |
| Example | (Co)polymer | mass | mass | Mw |
| Example | CP-1 | — | 0.95 | 17,800 |
| 1 | | | | |
| Example | CP-2 | — | 0.72 | 23,300 |
| 2 | | | | |
| Example | CP-3 | — | 0.54 | 29,200 |
| 3 | | | | |
| Example | CP-4 | — | 0.37 | 35,700 |
| 4 | | | | |
| Example | CP-5 | — | 0.24 | 47,100 |
| 5 | | | | |
| Example | CP-6 | — | 0.20 | 51,300 |
| 6 | | | | |
| Example | CP-7 | 0.26 | 1.61 | 4,100 |
| 7 | | | | |
| Example | CP-8 | — | 0.25 | 41,600 |
| 8 | | | | |
| Example | CP-9 | — | 0.13 | 52,200 |
| 9 | | | | |
| Example | CP-10 | 0.16 | 1.01 | 4,300 |
| 10 | | | | |
| Example | CP-11 | — | 0.88 | 18,100 |
| 11 | | | | |
| Example | CP-12 | — | 0.71 | 24,600 |
| 12 | | | | |
| Example | CP-13 | — | 0.67 | 30,100 |
| 13 | | | | |
| Example | CP-14 | — | 0.57 | 36,200 |
| 14 | | | | |
| Example | CP-15 | — | 0.35 | 46,900 |
| 15 | | | | |
| Example | CP-16 | — | 0.28 | 53,400 |
| 16 | | | | |
| Example | CP-17 | 0.30 | 1.86 | 4,100 |
| 17 | | | | |
| Example | CP-18 | — | 0.32 | 42,600 |
| 18 | | | | |
| Example | CP-19 | — | 0.16 | 52,800 |
| 19 | | | | |
| Example | CP-20 | 0.20 | 1.26 | 4,500 |
| 20 | | | | |
| Example | CP-21 | — | 0.90 | 19,700 |
| 21 | | | | |
| Example | CP-22 | — | 0.75 | 23,900 |
| 22 | | | | |
| Example | CP-23 | — | 0.55 | 29,800 |
| 23 | | | | |
| Example | CP-24 | — | 0.51 | 35,100 |
| 24 | | | | |
| Example | CP-25 | — | 0.35 | 43,800 |
| 25 | | | | |
| Example | CP-26 | — | 0.21 | 54,100 |
| 26 | | | | |
| Example | CP-27 | 0.27 | 1.68 | 4,600 |
| 27 | | | | |
| Example | CP-28 | — | 0.27 | 40,900 |
| 28 | | | | |
| Example | CP-29 | — | 0.13 | 56,200 |
| 29 | | | | |
| Example | CP-30 | 0.17 | 1.68 | 4,700 |
| 30 | | | | |

TABLE 4

| | | Monomer | | | | | | | |
|---|---|---|---|---|---|---|---|---|---|
| | | First | | Second | | Third | | Third | |
| | | monomer | | monomer | | monomer (1) | | monomer (2) | |
| | | | parts | | parts | | parts | | parts |
| | | | by | | by | | by | | by |
| Example | (Co)polymer | Type | mass | Type | mass | Type | mass | Type | mass |
| Example 31 | CP-31 | M-16 | 75.0 | MA | 25.0 | — | — | — | — |
| Example 32 | CP-32 | M-17 | 80.0 | MA | 20.0 | — | — | — | — |
| Example 33 | CP-33 | M-18 | 85.0 | MA | 15.0 | — | — | — | — |
| Example 34 | CP-34 | M-19 | 90.0 | MA | 10.0 | — | — | — | — |
| Example 35 | CP-35 | M-20 | 95.0 | MA | 5.0 | — | — | — | — |
| Example 36 | CP-36 | M-3 | 70.0 | MA | 20.0 | St | 10.0 | — | — |
| Example 37 | CP-37 | M-3 | 70.0 | MA | 20.0 | DdMA | 10.0 | — | — |
| Example 38 | CP-38 | M-3 | 70.0 | — | — | AAMS | 20.0 | St | 10.0 |
| Example 39 | CP-39 | M-3 | 70.0 | — | — | AAMS | 20.0 | St | 10.0 |
| Example 40 | CP-40 | M-3 | 70.0 | — | — | AAMS | 20.0 | St | 10.0 |
| Comparative | RCP1 | RM-1 | 75.0 | AA | 25.0 | — | — | — | — |
| Example 1 | | | | | | | | | |
| Comparative | RCP2 | RM-1 | 85.0 | AA | 15.0 | — | — | — | — |
| Example 2 | | | | | | | | | |
| Comparative | RCP3 | RM-1 | 95.0 | AA | 5.0 | — | — | — | — |
| Example 3 | | | | | | | | | |
| Comparative | RCP4 | RM-1 | 80.0 | — | — | AAMS | 20.0 | — | — |
| Example 4 | | | | | | | | | |
| Comparative | RCP5 | RM-1 | 80.0 | — | — | AAMS | 20.0 | — | — |
| Example 5 | | | | | | | | | |
| Comparative | RCP6 | RM-1 | 80.0 | — | — | AAMS | 20.0 | — | — |
| Example 6 | | | | | | | | | |
| Comparative | RCP7 | RM-2 | 70.0 | MA | 25.0 | St | 5.0 | — | — |
| Example 7 | | | | | | | | | |
| Comparative | RCP8 | RM-2 | 70.0 | MA | 5.0 | DdMA | 25.0 | — | — |
| Example 8 | | | | | | | | | |
| Comparative | RCP9 | RM-2 | 70.0 | — | — | AAMS | 20.0 | St | 10.0 |
| Example 9 | | | | | | | | | |
| Comparative | RCP10 | RM-2 | 70.0 | — | — | AAMS | 20.0 | St | 10.0 |
| Example 10 | | | | | | | | | |
| Comparative | RCP11 | RM-2 | 70.0 | — | — | AAMS | 20.0 | St | 10.0 |
| Example 11 | | | | | | | | | |

| | | 3MPA | AIBN | |
|---|---|---|---|---|
| | | parts | parts | Weight average |
| | | by | by | molecular weight |
| Example | (Co)polymer | mass | mass | Mw |
| Example 31 | CP-31 | — | 0.77 | 18,800 |
| Example 32 | CP-32 | — | 0.64 | 23,000 |
| Example 33 | CP-33 | — | 0.48 | 30,100 |
| Example 34 | CP-34 | — | 0.44 | 35,900 |
| Example 35 | CP-35 | — | 0.30 | 45,700 |
| Example 36 | CP-36 | — | 0.49 | 37,900 |
| Example 37 | CP-37 | — | 0.43 | 38,600 |
| Example 38 | CP-38 | — | 0.35 | 39,900 |
| Example 39 | CP-39 | — | 0.15 | 55,500 |
| Example 40 | CP-40 | 0.19 | 1.18 | 4,000 |
| Comparative | RCP1 | — | 0.52 | 34,900 |
| Example 1 | | | | |
| Comparative | RCP2 | — | 0.40 | 35,300 |
| Example 2 | | | | |
| Comparative | RCP3 | — | 0.29 | 36,200 |
| Example 3 | | | | |
| Comparative | RCP4 | — | 0.28 | 36,300 |
| Example 4 | | | | |
| Comparative | RCP5 | — | 0.12 | 56,100 |
| Example 5 | | | | |
| Comparative | RCP6 | 0.15 | 0.94 | 4,600 |
| Example 6 | | | | |
| Comparative | RCP7 | — | 0.52 | 36,900 |
| Example 7 | | | | |
| Comparative | RCP8 | — | 0.34 | 37,100 |
| Example 8 | | | | |
| Comparative | RCP9 | — | 0.37 | 35,900 |
| Example 9 | | | | |
| Comparative | RCP10 | — | 0.16 | 53,700 |
| Example 10 | | | | |
| Comparative | RCP11 | 0.20 | 1.24 | 3,900 |
| Example 11 | | | | |

### Example 41

### Preparation of Pigment Dispersion PD-1

A total of 40.0 parts by mass of deionized water and 5.0 parts by mass of ethylene glycol (available from Tokyo Chemical Industry Co., Ltd.) were placed in a glass vessel, followed by stirring. A total of 1.16 parts by mass of (2-hydroxyethyl)dimethylamine (available from Tokyo Chemical Industry Co., Ltd.) and 3.75 parts by mass of Copolymer CP-1 prepared in Example 1 were added and dissolved. Next, 50.0 parts by mass of titanium oxide JR-405 (available from TAYCA CORPORATION) was added little by little during stirring, followed by stirring for 6 hours. A total of 540.0 parts by mass of 2 mm diameter zirconia beads was added to the vessel, followed by dispersion for 48 hours at a rotation speed of 90 rpm using a Big Rotor BR-2 (available from AS ONE Corporation). The contents were filtered through a membrane filter with a pore size of 10 μm, and the required amount of deionized water was added to make adjustments, resulting in 100.0 parts by mass of pigment dispersion PD-1 (pigment solid concentration: 50 percent).

### Preparation of Ink (Aqueous Ink) 1

A mixture of 20.0 parts by mass of Pigment Dispersion PD-1, 18.0 parts by mass of ethylene glycol, 4.0 parts by mass of 3-methoxy-N,N-dimethylpropionamide (available from Tokyo Chemical Industry Co., Ltd.), 1.0 part by mass of Zonyl FS-300 (fluorochemical surfactant, with a solid content of 40 percent, available from E.I. du Pont de Nemours and Company), 0.3 parts by mass of triethanolamine (available from Tokyo Chemical Industry Co., Ltd.), 0.8 parts by mass of 1,2-benzothiazole-3-one (available from Tokyo Chemical Industry Co., Ltd.), and 56.0 parts by mass of deionized water was stirred for 1 hour. The mixture was then filtered through a membrane filter with a pore size of 5.0 m to obtain Aqueous Ink 1.

### Example 42

### Preparation of Aqueous Ink 2

Pigment Dispersion PD-2 and Aqueous Ink 2 were obtained in the same manner as in Example 41 except that Copolymer CP-2 prepared in Example 2 was used instead of Copolymer CP-1 used in Example 41 and 1.16 parts by mass of (2-hydoxyethyl)dimethyhl amine used in Example 41 was replaced with 0.93 parts by mass of (2-hydroxyethyl)dimethyl amine.

### Example 43

### Preparation of Aqueous Ink-3

Pigment Dispersion PD-3 and Aqueous Ink 3 were obtained in the same manner as in Example 41 except that Copolymer CP-3 prepared in Example 2 was used instead of Copolymer CP-1 used in Example 41 and 1.16 parts by mass of (2-hydoxyethyl)dimethyhl amine used in Example 41 was replaced with 0.70 parts by mass of (2-hydroxyethyl)dimethyl amine.

### Example 44

### Preparation of Aqueous Ink 4

Pigment Dispersion PD-4 and Aqueous Ink 4 were obtained in the same manner as in Example 41 except that Copolymer CP-4 prepared in Example 2 was used instead of Copolymer CP-1 used in Example 41 and 1.16 parts by mass of (2-hydoxyethyl)dimethyhl amine used in Example 41 was replaced with 0.46 parts by mass of (2-hydroxyethyl)dimethyl amine.

### Example 45

### Preparation of Aqueous Ink 5

Pigment Dispersion PD-5 and Aqueous Ink 5 were obtained in the same manner as in Example 41 except that Copolymer CP-5 prepared in Example 5 was used instead of Copolymer CP-1 used in Example 41 and 1.16 parts by mass of (2-hydoxyethyl)dimethyhl amine used in Example 41 was replaced with 0.23 parts by mass of (2-hydroxyethyl)dimethyl amine.

### Example 46

### Preparation of Aqueous Ink 6

Pigment Dispersion PD-6 and Aqueous Ink 6 were obtained in the same manner as in Example 41 except that Copolymer CP-6 prepared in Example 6 was used instead of Copolymer CP-1 used in Example 41 and 1.16 parts by mass of (2-hydoxyethyl)dimethyhl amine used in Example 41 was replaced with 0.93 parts by mass of (2-hydroxyethyl)dimethyl amine.

### Example 47

### Preparation of Aqueous Ink 7

Pigment Dispersion PD-7 and Aqueous Ink 7 were obtained in the same manner as in Example 41 except that Copolymer CP-7 prepared in Example 7 was used instead of Copolymer CP-1 used in Example 41 and 1.16 parts by mass of (2-hydoxyethyl)dimethyhl amine used in Example 41 was replaced with 0.93 parts by mass of (2-hydroxyethyl)dimethyl amine.

### Example 48

### Preparation of Aqueous Ink 8

Pigment Dispersion PD-8 and Aqueous Ink 8 were obtained in the same manner as in Example 41 except that Copolymer CP-8 prepared in Example 8 was used instead of Copolymer CP-1 used in Example 41 and 1.16 parts by mass of (2-hydoxyethyl)dimethyhl amine used in Example 41 was replaced with 0.32 parts by mass of (2-hydroxyethyl)dimethyl amine.

### Example 49

### Preparation of Aqueous Ink 9

Pigment Dispersion PD-9 and Aqueous Ink 9 were obtained in the same manner as in Example 41 except that Copolymer CP-9 prepared in Example 9 was used instead of Copolymer CP-1 used in Example 41 and 1.16 parts by mass of (2-hydoxyethyl)dimethyhl amine used in Example 41 was replaced with 0.32 parts by mass of (2-hydroxyethyl)dimethyl amine.

### Example 50

### Preparation of Aqueous Ink 10

Pigment Dispersion PD-10 and Aqueous Ink 10 were obtained in the same manner as in Example 41 except that Copolymer CP-10 prepared in Example 10 was used instead of Copolymer CP-1 used in Example 41 and 1.16 parts by mass of (2-hydoxyethyl)dimethyhl amine used in Example 41 was replaced with 0.32 parts by mass of (2-hydroxyethyl)dimethyl amine.

### Example 51

### Preparation of Aqueous Ink 11

Pigment Dispersion PD-11 and Aqueous Ink 11 were obtained in the same manner as in Example 41 except that 2.50 parts by mass of Copolymer CP-11 prepared in Example 11 was used instead of 3.75 parts by mass of Copolymer CP-1 used in Example 41 and 1.16 parts by mass of (2-hydoxyethyl)dimethyhl amine used in Example 41 was replaced with 0.77 parts by mass of (2-hydroxyethyl)dimethyl amine.

### Example 52

### Preparation of Aqueous Ink 12

Pigment Dispersion PD-12 and Aqueous Ink 12 were obtained in the same manner as in Example 41 except that 2.50 parts by mass of Copolymer CP-12 prepared in Example 12 was used instead of 3.75 parts by mass of Copolymer CP-1 used in Example 41 and 1.16 parts by mass of (2-hydoxyethyl)dimethyhl amine used in Example 41 was replaced with 0.62 parts by mass of (2-hydroxyethyl)dimethyl amine.

### Example 53

### Preparation of Aqueous Ink 13

Pigment Dispersion PD-13 and Aqueous Ink 13 were obtained in the same manner as in Example 41 except that 2.50 parts by mass of Copolymer CP-13 prepared in Example 13 was used instead of 3.75 parts by mass of Copolymer CP-1 used in Example 41 and 1.16 parts by mass of (2-hydoxyethyl)dimethyhl amine used in Example 41 was replaced with 0.46 parts by mass of (2-hydroxyethyl)dimethyl amine.

### Example 54

### Preparation of Aqueous Ink 14

The pigment dispersion PD-14 and Aqueous Ink 14 were obtained in the same manner as in Example 41 except that 2.50 parts by mass of the copolymer CP-14 prepared in Example 14 was used instead of 3.75 parts by mass of Copolymer CP-1 used in Example 41 and 1.16 parts by mass of (2-hydoxyethyl)dimethyhl amine used in Example 41 was replaced with 0.31 parts by mass of (2-hydroxyethyl)dimethyl amine.

### Example 55

### Preparation of Aqueous Ink 15

The pigment dispersion PD-15 and Aqueous Ink 15 were obtained in the same manner as in Example 41 except that 2.50 parts by mass of the copolymer CP-15 prepared in Example 15 was used instead of 3.75 parts by mass of Copolymer CP-1 used in Example 41 and 1.16 parts by mass of (2-hydoxyethyl)dimethyhl amine used in Example 41 was replaced with 0.15 parts by mass of (2-hydroxyethyl)dimethyl amine.

### Example 56

### Preparation of Aqueous Ink 16

The pigment dispersion PD-16 and Aqueous Ink 16 were obtained in the same manner as in Example 41 except that 2.50 parts by mass of the copolymer CP-16 prepared in Example 16 was used instead of 3.75 parts by mass of Copolymer CP-1 used in Example 41 and 1.16 parts by mass of (2-hydoxyethyl)dimethyhl amine used in Example 41 was replaced with 0.62 parts by mass of (2-hydroxyethyl)dimethyl amine.

### Example 57

### Preparation of Aqueous Ink 17

The pigment dispersion PD-17 and Aqueous Ink 17 were obtained in the same manner as in Example 41 except that 2.50 parts by mass of the copolymer CP-17 prepared in Example 17 was used instead of 3.75 parts by mass of Copolymer CP-1 used in Example 41 and 1.16 parts by mass of (2-hydoxyethyl)dimethyhl amine used in Example 41 was replaced with 0.62 parts by mass of (2-hydroxyethyl)dimethyl amine.

### Example 58

### Preparation of Aqueous Ink 18

The pigment dispersion PD-18 and Aqueous Ink 18 were obtained in the same manner as in Example 41 except that 2.50 parts by mass of the copolymer CP-18 prepared in Example 18 was used instead of 3.75 parts by mass of Copolymer CP-1 used in Example 41 and 1.16 parts by mass of (2-hydoxyethyl)dimethyhl amine used in Example 41 was replaced with 0.22 parts by mass of (2-hydroxyethyl)dimethyl amine.

### Example 59

### Preparation of Aqueous Ink 19

The pigment dispersion PD-19 and Aqueous Ink 19 were obtained in the same manner as in Example 41 except that 2.50 parts by mass of the copolymer CP-19 prepared in Example 19 was used instead of 3.75 parts by mass of Copolymer CP-1 used in Example 41 and 1.16 parts by mass of (2-hydoxyethyl)dimethyhl amine used in Example 41 was replaced with 0.22 parts by mass of (2-hydroxyethyl)dimethyl amine.

### Example 60

### Preparation of Aqueous Ink-20

The pigment dispersion PD-20 and Aqueous Ink 20 were obtained in the same manner as in Example 41 except that 2.50 parts by mass of the copolymer CP-20 prepared in Example 20 was used instead of 3.75 parts by mass of Copolymer CP-1 used in Example 41 and 1.16 parts by mass of (2-hydoxyethyl)dimethyhl amine used in Example 41 was replaced with 0.22 parts by mass of (2-hydroxyethyl)dimethyl amine.

### Example 61

### Preparation of Pigment Dispersion PD-21

A total of 40.0 parts by mass of deionized water and 5.0 parts by mass of ethylene glycol (available from Tokyo Chemical Industry Co., Ltd.) were placed in a glass vessel, followed by stirring. A total of 0.52 parts by mass of sodium hydroxide (available from Kanto Chemical Co., Inc.) and 3.75 parts by mass of Copolymer CP-21 prepared in Example 21 were added and dissolved. Next, 50.0 parts by mass of titanium oxide JR-405 (available from TAYCA CORPORATION) was added little by little during stirring, followed by stirring for 6 hours. A total of 540.0 parts by mass of 2 mm diameter zirconia beads was added to the vessel, followed by dispersion for 48 hours at a rotation speed of 90 rpm using a Big Rotor BR-2 (available from AS ONE Corporation). The contents were filtered through a membrane filter with a pore size of 10 μm, and the required amount of deionized water was added to make adjustments, resulting in 100.0 parts by mass of Pigment Dispersion PD-21 (pigment solid concentration: 50 percent).

### Preparation of Aqueous Ink 21

Aqueous Ink 21 was obtained in the same manner as in Example 41 except that Pigment Dispersion PD-21 was used instead of Pigment Dispersion PD-1 used in Example 41.

### Example 62

Pigment Dispersion PD-22 and Aqueous Ink 22 were obtained in the same manner as in Example 61 except that Copolymer CP-22 prepared in Example 22 was used instead of Copolymer CP-21 used in Example 61 and 0.52 parts by mass of sodium hydroxide used in Example 61 was replaced with 0.42 parts by mass of sodium hydroxide.

### Example 63

The pigment dispersion PD-23 and Aqueous Ink 23 were obtained in the same manner as in Example 61 except that the copolymer CP-23 prepared in Example 23 was used instead of the copolymer CP-21 used in Example 61 and 0.52 parts by mass of sodium hydroxide used in Example 61 was replaced with 0.31 parts by mass of sodium hydroxide.

### Example 64

The pigment dispersion PD-24 and Aqueous Ink 24 were obtained in the same manner as in Example 61 except that the copolymer CP-24 prepared in Example 24 was used instead of the copolymer CP-21 used in Example 61 and 0.52 parts by mass of sodium hydroxide used in Example 61 was replaced with 0.21 parts by mass of sodium hydroxide.

### Example 65

The pigment dispersion PD-25 and Aqueous Ink 25 were obtained in the same manner as in Example 61 except that the copolymer CP-25 prepared in Example 25 was used instead of the copolymer CP-21 used in Example 61 and 0.52 parts by mass of sodium hydroxide used in Example 61 was replaced with 0.10 parts by mass of sodium hydroxide.

### Example 66

The pigment dispersion PD-26 and Aqueous Ink 26 were obtained in the same manner as in Example 61 except that the copolymer CP-26 prepared in Example 26 was used instead of the copolymer CP-21 used in Example 61 and 0.52 parts by mass of sodium hydroxide used in Example 61 was replaced with 0.42 parts by mass of sodium hydroxide.

### Example 67

Pigment Dispersion PD-27 and Aqueous Ink 27 were obtained in the same manner as in Example 61 except that Copolymer CP-27 prepared in Example 22 was used instead of Copolymer CP-21 used in Example 61 and 0.52 parts by mass of sodium hydroxide used in Example 61 was replaced with 0.42 parts by mass of sodium hydroxide.

### Example 68

Pigment Dispersion PD-28 and Aqueous Ink 28 were obtained in the same manner as in Example 61 except that Copolymer CP-28 prepared in Example 22 was used instead of Copolymer CP-21 used in Example 61 and 0.52 parts by mass of sodium hydroxide used in Example 61 was replaced with 0.14 parts by mass of sodium hydroxide.

### Example 69

Pigment Dispersion PD-29 and Aqueous Ink 29 were obtained in the same manner as in Example 61 except that Copolymer CP-29 prepared in Example 22 was used instead of Copolymer CP-21 used in Example 61 and 0.52 parts by mass of sodium hydroxide used in Example 61 was replaced with 0.14 parts by mass of sodium hydroxide.

### Example 70

Pigment Dispersion PD-30 and Aqueous Ink 30 were obtained in the same manner as in Example 61 except that Copolymer CP-30 prepared in Example 22 was used instead of Copolymer CP-21 used in Example 61 and 0.52 parts by mass of sodium hydroxide used in Example 61 was replaced with 0.14 parts by mass of sodium hydroxide.

### Example 71

Pigment Dispersion PD-31 and Aqueous Ink 31 were obtained in the same manner as in Example 61 except that 2.50 parts by mass of Copolymer CP-31 prepared in Example 11 was used instead of 3.75 parts by mass of Copolymer CP-21 used in Example 61 and 0.52 parts by mass of sodium hydroxide used in Example 61 was replaced with 0.29 parts by mass of sodium hydroxide.

### Example 72

Pigment Dispersion PD-32 and Aqueous Ink 32 were obtained in the same manner as in Example 61 except that 2.50 parts by mass of Copolymer CP-32 prepared in Example 11 was used instead of 3.75 parts by mass of Copolymer CP-21 used in Example 61 and 0.52 parts by mass of sodium hydroxide used in Example 61 was replaced with 0.23 parts by mass of sodium hydroxide.

### Example 73

Pigment Dispersion PD-33 and Aqueous Ink 33 were obtained in the same manner as in Example 61 except that 2.50 parts by mass of Copolymer CP-33 prepared in Example 11 was used instead of 3.75 parts by mass of Copolymer CP-21 used in Example 61 and 0.52 parts by mass of sodium hydroxide used in Example 61 was replaced with 0.17 parts by mass of sodium hydroxide.

### Example 74

Pigment Dispersion PD-34 and Aqueous Ink 34 were obtained in the same manner as in Example 61 except that 2.50 parts by mass of Copolymer CP-34 prepared in Example 11 was used instead of 3.75 parts by mass of Copolymer CP-21 used in Example 61 and 0.52 parts by mass of sodium hydroxide used in Example 61 was replaced with 0.12 parts by mass of sodium hydroxide.

### Example 75

Pigment Dispersion PD-35 and Aqueous Ink 35 were obtained in the same manner as in Example 61 except that 2.50 parts by mass of Copolymer CP-35 prepared in Example 11 was used instead of 3.75 parts by mass of Copolymer CP-21 used in Example 61 and 0.52 parts by mass of sodium hydroxide used in Example 61 was replaced with 0.06 parts by mass of sodium hydroxide.

### Example 76

Pigment Dispersion PD-36 and Aqueous Ink 36 were obtained in the same manner as in Example 61 except that 2.50 parts by mass of Copolymer CP-36 prepared in Example 11 was used instead of 3.75 parts by mass of Copolymer CP-21 used in Example 61 and 0.52 parts by mass of sodium hydroxide used in Example 61 was replaced with 0.23 parts by mass of sodium hydroxide.

### Example 77

Pigment Dispersion PD-37 and Aqueous Ink 37 were obtained in the same manner as in Example 61 except that 2.50 parts by mass of Copolymer CP-37 prepared in Example 11 was used instead of 3.75 parts by mass of Copolymer CP-21 used in Example 61 and 0.52 parts by mass of sodium hydroxide used in Example 61 was replaced with 0.23 parts by mass of sodium hydroxide.

### Example 78

Pigment Dispersion PD-38 and Aqueous Ink 38 were obtained in the same manner as in Example 61 except that 2.50 parts by mass of Copolymer CP-38 prepared in Example 11 was used instead of 3.75 parts by mass of Copolymer CP-21 used in Example 61 and 0.52 parts by mass of sodium hydroxide used in Example 61 was replaced with 0.10 parts by mass of sodium hydroxide.

### Example 79

Pigment Dispersion PD-39 and Aqueous Ink 39 were obtained in the same manner as in Example 61 except that 2.50 parts by mass of Copolymer CP-39 prepared in Example 11 was used instead of 3.75 parts by mass of Copolymer CP-21 used in Example 61 and 0.52 parts by mass of sodium hydroxide used in Example 61 was replaced with 0.10 parts by mass of sodium hydroxide.

### Example 80

Pigment Dispersion PD-40 and Aqueous Ink 40 were obtained in the same manner as in Example 61 except that 2.50 parts by mass of Copolymer CP-40 prepared in Example 11 was used instead of 3.75 parts by mass of Copolymer CP-21 used in Example 61 and 0.52 parts by mass of sodium hydroxide used in Example 61 was replaced with 0.10 parts by mass of sodium hydroxide.

### Example 81

### Preparation of Pigment Dispersion PD-41

A total of 40.0 parts of deionized water and 5.0 parts of ethylene glycol were placed in a glass vessel, followed by stirring. A total of 0.77 parts by mass of (2-hydroxyethyl)dimethylamine and 2.50 parts of Copolymer CP-1 prepared in Example 1 were added and dissolved. Next, 50.0 parts by mass of barium sulfate TS-2 (available from Takehara Kagaku Kogyo Co., Ltd.) was added little by little during stirring, followed by stirring for 6 hours. A total of 540.0 parts by mass of 2 mm diameter zirconia beads was added to the vessel, followed by dispersion for 48 hours at a rotation speed of 90 rpm using a Big Rotor BR-2 (available from AS ONE Corporation). The contents were filtered through a membrane filter with a pore size of 10 μm, and the required amount of deionized water was added to make adjustments, resulting in 100.0 parts by mass of Pigment Dispersion PD-41 (pigment solid concentration: 50 percent).

### Preparation of Aqueous Ink 41

Aqueous Ink 21 was obtained in the same manner as in Example 41 except that Pigment Dispersion PD-41 was used instead of Pigment Dispersion PD-1 used in Example 41.

### Example 82

Pigment Dispersion PD-42 and Aqueous Ink 42 were obtained in the same manner as in Example 81 except that Copolymer CP-2 prepared in Example 2 was used instead of Copolymer CP-1 used in Example 81 and 0.77 parts by mass of (2-hydoxyethyl)dimethyhl amine used in Example 81 was replaced with 0.62 parts by mass of (2-hydroxyethyl)dimethyl amine.

### Example 83

Pigment Dispersion PD-43 and Aqueous Ink 43 were obtained in the same manner as in Example 81 except that Copolymer CP-3 prepared in Example 2 was used instead of Copolymer CP-1 used in Example 81 and 0.77 parts by mass of (2-hydoxyethyl)dimethyhl amine used in Example 81 was replaced with 0.46 parts by mass of (2-hydroxyethyl)dimethyl amine.

### Example 84

The pigment dispersion PD-44 and Aqueous Ink 44 were obtained in the same manner as in Example 81 except that the copolymer CP-4 prepared in Example 4 was used instead of the copolymer CP-1 used in Example 81 and 0.77 parts of (2-hydoxyethyl)dimethyhl amine used in Example 81 was replaced with 0.31 parts of (2-hydroxyethyl)dimethyl amine.

### Example 85

Pigment Dispersion PD-45 and Aqueous Ink 45 were obtained in the same manner as in Example 81 except that Copolymer CP-5 prepared in Example 5 was used instead of Copolymer CP-1 used in Example 81 and 0.77 parts by mass of (2-hydoxyethyl)dimethyhl amine used in Example 81 was replaced with 0.15 parts by mass of (2-hydroxyethyl)dimethyl amine.

### Example 86

Pigment Dispersion PD-46 and Aqueous Ink 46 were obtained in the same manner as in Example 81 except that Copolymer CP-6 prepared in Example 6 was used instead of Copolymer CP-1 used in Example 81 and 0.77 parts by mass of (2-hydoxyethyl)dimethyhl amine used in Example 81 was replaced with 0.62 parts by mass of (2-hydroxyethyl)dimethyl amine.

### Example 87

Pigment Dispersion PD-47 and Aqueous Ink 47 were obtained in the same manner as in Example 81 except that Copolymer CP-7 prepared in Example 7 was used instead of Copolymer CP-1 used in Example 81 and 0.77 parts by mass of (2-hydoxyethyl)dimethyhl amine used in Example 81 was replaced with 0.62 parts by mass of (2-hydroxyethyl)dimethyl amine.

### Example 88

Pigment Dispersion PD-48 and Aqueous Ink 48 were obtained in the same manner as in Example 81 except that Copolymer CP-8 prepared in Example 8 was used instead of Copolymer CP-1 used in Example 81 and 0.77 parts by mass of (2-hydoxyethyl)dimethyhl amine used in Example 81 was replaced with 0.77 parts by mass of (2-hydroxyethyl)dimethyl amine.

### Example 89

Pigment Dispersion PD-49 and Aqueous Ink 49 were obtained in the same manner as in Example 81 except that Copolymer CP-9 prepared in Example 9 was used instead of Copolymer CP-1 used in Example 81 and 0.77 parts by mass of (2-hydoxyethyl)dimethyhl amine used in Example 81 was replaced with 0.22 parts by mass of (2-hydroxyethyl)dimethyl amine.

### Example 90

Pigment Dispersion PD-50 and Aqueous Ink 50 were obtained in the same manner as in Example 81 except that Copolymer CP-10 prepared in Example 10 was used instead of Copolymer CP-1 used in Example 81 and 0.77 parts by mass of (2-hydoxyethyl)dimethyhl amine used in Example 81 was replaced with 0.22 parts by mass of (2-hydroxyethyl)dimethyl amine.

### Comparative Example 12

### Preparation of Comparative Aqueous Rink 1

Comparative Pigment Dispersion RPD-1 and Comparative Aqueous Rink 1 were obtained in the same manner as in Example 41 except that Comparative Copolymer RCP-1 prepared in Comparative Example 1 was used instead of the Copolymer CP-1 used in Example 41 and 1.16 parts by mass of (2-hydoxyethyl)dimethyhl amine used in Example 41 was replaced with 1.16 parts by mass of (2-hydroxyethyl)dimethyl amine.

### Comparative Example 13

### Preparation of Comparative Aqueous Rink 2

Comparative Pigment Dispersion RPD-2 and Comparative Aqueous Rink 2 were obtained in the same manner as in Example 41 except that Comparative Copolymer RCP-2 prepared in Comparative Example 3 was used instead of Copolymer CP-1 used in Example 41 and 1.16 parts by mass of (2-hydoxyethyl)dimethyhl amine used in Example 41 was replaced with 0.70 parts by mass of (2-hydroxyethyl)dimethyl amine.

### Comparative Example 14

### Preparation of Comparative Aqueous Rink 3

Comparative Pigment Dispersion RPD-3 and Comparative Aqueous Rink 3 were obtained in the same manner as in Example 41 except that Comparative Copolymer RCP-3 prepared in Comparative Example 3 was used instead of Copolymer CP-1 used in Example 41 and 1.16 parts by mass of (2-hydoxyethyl)dimethyhl amine used in Example 41 was replaced with 0.23 parts by mass of (2-hydroxyethyl)dimethyl amine.

### Comparative Example 15

### Preparation of Comparative Aqueous Rink 4

Comparative Pigment Dispersion RPD-4 and Comparative Aqueous Rink 4 were obtained in the same manner as in Example 41 except that Comparative Copolymer RCP-4 prepared in Comparative Example 4 was used instead of Copolymer CP-1 used in Example 41 and 1.16 parts by mass of (2-hydoxyethyl)dimethyhl amine used in Example 41 was replaced with 0.32 parts by mass of (2-hydroxyethyl)dimethyl amine.

### Comparative Example 16

### Preparation of Comparative Aqueous Rink 5

Comparative Pigment Dispersion RPD-5 and Comparative Aqueous Rink 5 were obtained in the same manner as in Example 41 except that Comparative Copolymer RCP-5 prepared in Comparative Example 5 was used instead of Copolymer CP-1 used in Example 41 and 1.16 parts by mass of (2-hydoxyethyl)dimethyhl amine used in Example 41 was replaced with 0.32 parts by mass of (2-hydroxyethyl)dimethyl amine.

### Comparative Example 17

### Preparation of Comparative Aqueous Rink 6

Comparative Pigment Dispersion RPD-6 and Comparative Aqueous Rink 6 were obtained in the same manner as in Example 41 except that Comparative Copolymer RCP-6 prepared in Comparative Example 6 was used instead of Copolymer CP-1 used in Example 41 and 1.16 parts by mass of (2-hydoxyethyl)dimethyhl amine used in Example 41 was replaced with 0.32 parts by mass of (2-hydroxyethyl)dimethyl amine.

### Comparative Example 18

### Preparation of Comparative Aqueous Rink 7

Comparative Pigment Dispersion RPD-7 and Comparative Aqueous Rink 7 were obtained in the same manner as in Example 61 except that 2.50 parts by mass of Comparative Copolymer RCP-7 prepared in Comparative Example 7 was used instead of 3.75 parts by mass of Copolymer CP-21 used in Example 61 and 0.52 parts by mass of sodium hydroxide used in Example 61 was replaced with 0.29 parts by mass of sodium hydroxide.

### Comparative Example 19

### Preparation of Comparative Aqueous Rink 8

Comparative Pigment Dispersion RPD-8 and Comparative Aqueous Rink 8 were obtained in the same manner as in Example 61 except that 2.50 parts by mass of Comparative Copolymer RCP-8 prepared in Comparative Example 8 was used instead of 3.75 parts by mass of Copolymer CP-21 used in Example 61 and 0.52 parts by mass of sodium hydroxide used in Example 61 was replaced with 0.06 parts by mass of sodium hydroxide.

### Comparative Example 20

### Preparation of Comparative Aqueous Rink 9

Comparative Pigment Dispersion RPD-9 and Comparative Aqueous Rink 9 were obtained in the same manner as in Example 61 except that 2.50 parts by mass of Comparative Copolymer RCP-9 prepared in Comparative Example 9 was used instead of 3.75 parts by mass of Copolymer CP-21 used in Example 61 and 0.52 parts by mass of sodium hydroxide used in Example 61 was replaced with 0.10 parts by mass of sodium hydroxide.

### Comparative Example 21

### Preparation of Comparative Aqueous Rink 10

Comparative Pigment Dispersion RPD-10 and Comparative Aqueous Rink 10 were obtained in the same manner as in Example 61 except that 2.50 parts by mass of Comparative Copolymer RCP-10 prepared in Comparative Example 10 was used instead of 3.75 parts by mass of Copolymer CP-21 used in Example 61 and 0.52 parts by mass of sodium hydroxide used in Example 61 was replaced with 0.10 parts by mass of sodium hydroxide.

### Comparative Example 22

### Preparation of Comparative Aqueous Rink 11

Comparative Pigment Dispersion RPD-11 and Comparative Aqueous Rink 11 were obtained in the same manner as in Example 61 except that 2.50 parts by mass of Comparative Copolymer RCP-11 prepared in Comparative Example 11 was used instead of 3.75 parts by mass of Copolymer CP-21 used in Example 61 and 0.52 parts by mass of sodium hydroxide used in Example 61 was replaced with 0.10 parts by mass of sodium hydroxide.

### Comparative Example 23

### Preparation of Comparative Aqueous Rink 12

Comparative Pigment Dispersion RPD-12 and Comparative Aqueous Rink 12 were obtained in the same manner as in Example 81 except that Comparative Copolymer RCP-1 prepared in Comparative Example 1 was used instead of Copolymer CP-1 used in Example 81 and 0.77 parts by mass of (2-hydoxyethyl)dimethyhl amine used in Example 81 was replaced with 0.62 parts by mass of (2-hydroxyethyl)dimethyl amine.

### Comparative Example 24

### Preparation of Comparative Aqueous Rink 13

Comparative Pigment Dispersion RPD-13 and Comparative Aqueous Rink 13 were obtained in the same manner as in Example 81 except that Comparative Copolymer RCP-2 prepared in Comparative Example 2 was used instead of Copolymer CP-1 used in Example 81 and 0.77 parts by mass of (2-hydoxyethyl)dimethyhl amine used in Example 81 was replaced with 0.62 parts by mass of (2-hydroxyethyl)dimethyl amine.

### Comparative Example 25

### Preparation of Comparative Aqueous Rink 14

Comparative Pigment Dispersion RPD-14 and Comparative Aqueous Rink 14 were obtained in the same manner as in Example 81 except that Comparative Copolymer RCP-3 prepared in Comparative Example 3 was used instead of Copolymer CP-1 used in Example 81 and 0.77 parts by mass of (2-hydoxyethyl)dimethyhl amine used in Example 81 was replaced with 0.62 parts by mass of (2-hydroxyethyl)dimethyl amine.

### Evaluation on Storage Stability of Pigment Dispersion

A glass container was filled with each pigment dispersion and stored at 70 degrees C. for two weeks. The change ratio of the viscosity after the storage to the viscosity before the storage was obtained from the following relationship and evaluated according to the following criteria. The viscosity was measured at 25 degrees C. at 50 rotations using a viscometer (RE80L, available from TOKI SANGYO CO., LTD.).

Viscosity change ratio (percent)=[(viscosity of pigment dispersion after storage−viscosity of pigment dispersion before storage)/viscosity of pigment dispersion before storage}×100

### Evaluation Criteria

A: The percentage change in viscosity ranges from −5 percent to +5 percent
B: The percentage change in viscosity exceeds −8 percent and falls within −5 percent, as well as exceeds 5 percent and falls within 8 percent
C: The percentage change in viscosity exceeds −10 percent and falls within −8 percent, as well as exceeds 8 percent and falls within 10 percent
D: The percentage change in viscosity exceeds −30 percent and falls within −10 percent, as well as exceeds 10 percent and falls within 30 percent

### Evaluation on Storage Stability of Ink

Each ink was filled into an ink cartridge and stored at 70 degrees for one week. The percentage change in viscosity after storage, relative to the viscosity before storage, was calculated using the following relationship and evaluated according to the criteria below. The viscosity was measured at 25 degrees C. at 50 rotations using a viscometer (RE80L, available from TOKI SANGYO CO., LTD.).

The change rate of viscosity (percent)=[(Viscosity of ink after storage−viscosity of ink before storage)/viscosity of ink before storage]×100

### Evaluation Criteria

A: The percentage change in viscosity ranges from −5 percent to +5 percent
B: The percentage change in viscosity exceeds −8 percent and falls within −5 percent, as well as exceeds 5 percent and falls within 8 percent
C: The percentage change in viscosity exceeds −10 percent and falls within −8 percent, as well as exceeds 8 percent and falls within 10 percent
D: The percentage change in viscosity exceeds −30 percent and falls within −10 percent, as well as exceeds 10 percent and falls within 30 percent

### Evaluation on Ink Re-dispersibility

The settling of ink components by resting requires a long period of standing, so centrifugation was employed to accelerate the sedimentation of ink components.

To create an evaluation sample, ink was poured into a test tube, PYREX® IWAKI TE-32 (16.5 mm×105 mm, available from AGC Inc.), to a depth of 45 mm and sealed with a silicone stopper. Subsequently, to define the initial state of the evaluation sample, immediately after preparing the evaluation sample, the tip of 2 to 3 mm of a pipette dropper was immersed in the ink to extract approximately 0.02 mL (approximately 20 mg) of ink. Out of the extracted ink, 4 to 10 mg was placed into a 50 mL sample bottle and diluted 4,000 times with deionized water. The sample bottle was then placed on the stand of a mix rotor VMR-5R (available from AS ONE CORPORATION) and rotated at a speed of 60 rpm for at least 10 minutes. Immediately after, the absorption spectrum was measured using UV-VIS (Ultraviolet-Visible Absorption Spectroscopy) spectrophotometer V-680 (available from JASCO Corporation), and it served as the reference spectrum before acceleration sedimentation. The conditions are specified below:

### UV-VIS Measuring Condition

Range of wavelength: 350 to 800 nm
Length of cell: 3 mm

Measuring conditions: UV/VIS band width of 2.0 nm; NIR band width of 4.0 nm; response of FAST; and scanning speed of 400 nm/minute

Next, the evaluation sample was placed into a Hematocrit Centrifuge Inverter 3220 (available from KUBOTA Corporation) and subjected to accelerated sedimentation at a rotation speed of 300 rpm for 14 hours. The retrieved evaluation sample was gently tilted sideways, then placed onto the mount of the mix rotor VMR-5R and rotated at a speed of 60 rpm for 1, 2, 3, or 4 minutes. Immediately after, the evaluation sample was returned to its original vertical position, and similarly, samples were collected from the surface of the ink, and the absorption spectrum was measured. The spectra obtained after 1, 2, 3, or 4 minutes were designated as the redistribution spectra.

The ink's re-dispersibility was evaluated by calculating the rate of change of the redispersion spectrum relative to the reference spectrum using the relationship below, and assessed according to the criteria below.

Re-dispersibility (percent)=100×(absorbency of the peak wavelength of re-dispersion spectrum/absorbency of peak wavelength of reference spectrum)

### Evaluation Criteria

A: Re-dispersibility was 90 percent or greater for the re-dispersion spectrum one minute later
B: Re-dispersibility was 90 percent or greater for the re-dispersion spectrum two minutes later
C: Re-dispersibility was 90 percent or greater for the re-dispersion spectrum three minutes later
D: Re-dispersibility was 90 percent or greater for the re-dispersion spectrum four minutes later
E: Re-dispersibility was 89 percent or less for the re-dispersion spectrum four minutes later

The results of the storage stability and re-dispersibility of Pigment Dispersion PD-1 to PD-50, Aqueous Ink 1 to Aqueous Ink 50 in Examples 41 to 90, and Comparative Pigment Dispersion RPD-1 to RPD-14, as well as Comparative Aqueous Rink 1 to Comparative Aqueous Rink 14 in Comparative Examples 12 to 25, are summarized in Tables 5 and 6.

TABLE 5

| | | | | Storage | Aqueous Ink | |
|---|---|---|---|---|---|---|
| | | Pigment | Aqueous | stability of | Storage | Re- |
| Example | (Co)polymer | dispersion | Ink | dispersion | stability | dispersibility |
| Example 41 | CP-1 | PD-1 | Aqueous | A | A | A |
| | | | Ink 1 | | | |
| Example 42 | CP-2 | PD-2 | Aqueous | A | A | A |
| | | | Ink 2 | | | |
| Example 43 | CP-3 | PD-3 | Aqueous | A | A | A |
| | | | Ink 3 | | | |
| Example 44 | CP-4 | PD-4 | Aqueous | A | A | A |
| | | | Ink 4 | | | |
| Example 45 | CP-5 | PD-5 | Aqueous | A | A | A |
| | | | Ink 5 | | | |
| Example 46 | CP-6 | PD-6 | Aqueous | A | A | C |
| | | | Ink 6 | | | |
| Example 47 | CP-7 | PD-7 | Aqueous | A | A | C |
| | | | Ink 7 | | | |
| Example 48 | CP-8 | PD-8 | Aqueous | B | B | B |
| | | | Ink 8 | | | |
| Example 49 | CP-9 | PD-9 | Aqueous | B | B | C |
| | | | Ink 9 | | | |
| Example 50 | CP-10 | PD-10 | Aqueous | B | B | C |
| | | | Ink 10 | | | |
| Example 51 | CP-11 | PD-11 | Aqueous | A | A | A |
| | | | Ink 11 | | | |
| Example 52 | CP-12 | PD-12 | Aqueous | A | A | A |
| | | | Ink 12 | | | |
| Example 53 | CP-13 | PD-13 | Aqueous | A | A | A |
| | | | Ink 13 | | | |
| Example 54 | CP-14 | PD-14 | Aqueous | A | A | A |
| | | | Ink 14 | | | |
| Example 55 | CP-15 | PD-15 | Aqueous | A | A | A |
| | | | Ink 15 | | | |
| Example 56 | CP-16 | PD-16 | Aqueous | A | A | C |
| | | | Ink 16 | | | |
| Example 57 | CP-17 | PD-17 | Aqueous | A | A | C |
| | | | Ink 17 | | | |
| Example 58 | CP-18 | PD-18 | Aqueous | B | B | B |
| | | | Ink 18 | | | |
| Example 59 | CP-19 | PD-19 | Aqueous | B | B | C |
| | | | Ink 19 | | | |
| Example 60 | CP-20 | PD-20 | Aqueous | B | B | C |
| | | | Ink 20 | | | |
| Example 61 | CP-21 | PD-21 | Aqueous | A | A | A |
| | | | Ink 21 | | | |
| Example 62 | CP-22 | PD-22 | Aqueous | A | A | A |
| | | | Ink 22 | | | |
| Example 63 | CP-23 | PD-23 | Aqueous | A | A | A |
| | | | Ink 23 | | | |
| Example 64 | CP-24 | PD-24 | Aqueous | A | A | A |
| | | | Ink 24 | | | |
| Example 65 | CP-25 | PD-25 | Aqueous | A | A | A |
| | | | Ink 25 | | | |
| Example 66 | CP-26 | PD-26 | Aqueous | A | A | C |
| | | | Ink 26 | | | |
| Example 67 | CP-27 | PD-27 | Aqueous | A | A | C |
| | | | Ink 27 | | | |
| Example 68 | CP-28 | PD-28 | Aqueous | B | B | B |
| | | | Ink 28 | | | |
| Example 69 | CP-29 | PD-29 | Aqueous | B | B | C |
| | | | Ink 29 | | | |
| Example 70 | CP-30 | PD-30 | Aqueous | B | B | C |
| | | | Ink 30 | | | |

TABLE 6

| | | | | Storage | Aqueous Ink | |
|---|---|---|---|---|---|---|
| | | Pigment | Aqueous | stability of | Storage | Re- |
| Example | (Co)polymer | dispersion | Ink | dispersion | stability | dispersibility |
| Example 71 | CP-31 | PD-31 | Aqueous | A | A | A |
| | | | Ink 31 | | | |
| Example 72 | CP-32 | PD-32 | Aqueous | A | A | A |
| | | | Ink 32 | | | |
| Example 73 | CP-33 | PD-33 | Aqueous | A | A | A |
| | | | Ink 33 | | | |
| Example 74 | CP-34 | PD-34 | Aqueous | A | A | A |
| | | | Ink 34 | | | |
| Example 75 | CP-35 | PD-35 | Aqueous | A | A | A |
| | | | Ink 35 | | | |
| Example 76 | CP-36 | PD-36 | Aqueous | A | A | A |
| | | | Ink 36 | | | |
| Example 77 | CP-37 | PD-37 | Aqueous | A | A | A |
| | | | Ink 37 | | | |
| Example 78 | CP-38 | PD-38 | Aqueous | B | B | B |
| | | | Ink 38 | | | |
| Example 79 | CP-39 | PD-39 | Aqueous | B | B | C |
| | | | Ink 39 | | | |
| Example 80 | CP-40 | PD-40 | Aqueous | B | B | B |
| | | | Ink 40 | | | |
| Example 81 | CP-1 | PD-41 | Aqueous | A | B | B |
| | | | Ink 41 | | | |
| Example 82 | CP-2 | PD-42 | Aqueous | A | B | B |
| | | | Ink 42 | | | |
| Example 83 | CP-3 | PD-43 | Aqueous | A | B | B |
| | | | Ink 43 | | | |
| Example 84 | CP-4 | PD-44 | Aqueous | A | B | B |
| | | | Ink 44 | | | |
| Example 85 | CP-5 | PD-45 | Aqueous | A | B | B |
| | | | Ink 45 | | | |
| Example 86 | CP-6 | PD-46 | Aqueous | B | B | C |
| | | | Ink 46 | | | |
| Example 87 | CP-7 | PD-47 | Aqueous | B | B | B |
| | | | Ink 47 | | | |
| Example 88 | CP-8 | PD-48 | Aqueous | B | B | B |
| | | | Ink 48 | | | |
| Example 89 | CP-9 | PD-49 | Aqueous | B | B | C |
| | | | Ink 49 | | | |
| Example 90 | CP-10 | PD-50 | Aqueous | B | B | B |
| | | | Ink 50 | | | |
| Comparative | RCP-1 | RPD-1 | Aqueous | C | C | D |
| Example 12 | | | Rink 1 | | | |
| Comparative | RCP-2 | RPD-2 | Aqueous | C | C | E |
| Example 13 | | | Rink 2 | | | |
| Comparative | RCP-3 | RPD-3 | Aqueous | C | C | D |
| Example 14 | | | Rink 3 | | | |
| Comparative | RCP-4 | RPD-4 | Aqueous | C | C | D |
| Example 15 | | | Rink 4 | | | |
| Comparative | RCP-5 | RPD-5 | Aqueous | C | C | E |
| Example 16 | | | Rink 5 | | | |
| Comparative | RCP-6 | RPD-6 | Aqueous | C | C | D |
| Example 17 | | | Rink 6 | | | |
| Comparative | RCP-7 | RPD-7 | Aqueous | C | C | D |
| Example 18 | | | Rink 7 | | | |
| Comparative | RCP-8 | RPD-8 | Aqueous | C | C | D |
| Example 19 | | | Rink 8 | | | |
| Comparative | RCP-9 | RPD-9 | Aqueous | C | C | D |
| Example 20 | | | Rink 9 | | | |
| Comparative | RCP-10 | RPD-10 | Aqueous | C | C | E |
| Example 21 | | | Rink 10 | | | |
| Comparative | RCP-11 | RPD-11 | Aqueous | C | C | D |
| Example 22 | | | Rink 11 | | | |
| Comparative | RCP-1 | RPD-12 | Aqueous | C | C | D |
| Example 23 | | | Rink 12 | | | |
| Comparative | RCP-2 | RPD-13 | Aqueous | C | C | E |
| Example 24 | | | Rink 13 | | | |
| Comparative | RCP-3 | RPD-14 | Aqueous | C | C | D |
| Example 25 | | | Rink 14 | | | |

### Example 91

### Preparation of Protection Layer Forming Liquid PC-1

A total of 45 parts by mass of dimethyl formamide (available from Kanto Chemical Co., Inc.) and 36 parts by mass of Copolymer CP-5 prepared in Example 5 were added to a glass vessel and dissolved by stirring. Then 10 parts of titanium oxide JR-405 were added little by little with stirring, followed by stirring for 6 hours. A total of 540.0 parts by mass of 1 mm diameter zirconia beads was added to the vessel, followed by dispersion with Big Rotor BR-2, available from AS ONE Corporation, at a rate of rotation of 90 rotation per minute (rpm) for 2 days. The contents were filtered through a membrane filter with a pore size of 10 μm, and adjusted amounts of dimethylformamide (available from Kanto Chemical Co., Inc.) and 4.0 parts of hexamethylene diisocyanate (available from Tokyo Chemical Industry Co., Ltd.) were added to obtain 100.0 parts of protection layer forming liquid PC-1 (pigment solid concentration: 10 percent).

### Manufacturing of Backsheet BS-1 for Solar Cell

A white polyethylene terephthalate film with a thickness of 75 μm (Lumirror MX11, available from Toray Industries, Inc.) was coated with protection layer forming liquid PC1 using a wire bar on the surface, and dried at 150 degrees for 5 minutes to provide a protection layer with an average thickness of 2 μm. Subsequently, the protection layer was aged at 50 degrees C. for 3 days to obtain Backsheet BS-1 for solar cell.

### Example 92

### Manufacturing of Backsheet BS-2 for Solar Cell

The protection layer forming liquid PC-2 and Backsheet BS-2 for solar cell were obtained in the same manner as in Example 91 except that Copolymer CP-15 prepared in Example 15 was used instead of Copolymer CP-5 used in Example 91.

### Example 93

### Manufacturing of Backsheet BS-3 for Solar Cell

The protection layer forming liquid PC-3 and Backsheet BS-3 for solar cell were obtained in the same manner as in Example 91 except that Copolymer CP-25 prepared in Example 25 was used instead of Copolymer CP-5 used in Example 91.

### Example 94

### Manufacturing of Backsheet BS-4 for Solar Cell

The protection layer forming liquid PC-4 and Backsheet BS-4 for solar cell were obtained in the same manner as in Example 91 except that Copolymer CP-35 prepared in Example 35 was used instead of Copolymer CP-5 used in Example 91.

### Comparative Example 26

### Manufacturing of Comparative Backsheet RBS-1 for Solar Cell

The comparative protection layer forming liquid RPC-1 and the Comparative Backsheet RBS-1 for solar cell were obtained in the same manner as in Example 91 except that Comparative Copolymer RCP-3 prepared in Comparative Example 3 was used instead of Copolymer CP-5 used in Example 91.

### Comparative Example 27

### Manufacturing of Backsheet RBS-2 for Solar Cell

The comparative protection layer forming liquid RPC-2 and Backsheet RBS-2 for solar cell were obtained in the same manner as in Example 91 except that Comparative Copolymer RCP-8 prepared in Comparative Example 8 was used instead of Copolymer CP-5 used in Example 91.

### Evaluation on Weatherability

### Measuring of Initial Fracture Elongation Es

Each of the manufactured Backsheets for solar cell was cut to have a size of 1 cm×10 cm and the cut sheet was measured regarding the fracture elongation of Backsheets for solar cell based on ASTM-D882 (Annual Book of ASTM STANDARDS, 1999 year version). The measurement results served as the initial fracture elongation Es.

### Measuring of Fracture Elongation Ee Over Time

Using a super Xenon weather meter SX 75 (available from Suga Test Instruments Co., Ltd.), test pieces of 10 cm×20 cm of Backsheets for solar cell were subjected to 108 minutes of ultraviolet irradiation and 12 minutes of ultraviolet irradiation with water spraying (without humidity control), which were repeated in conditions of a black panel temperature of 65 degrees C., relative humidity of 50 percent RH, and an irradiance of 180 W/m² (wavelength range: 300 to 400 nm), for a total of 3000 hours of UV exposure. Following this, the extracted test pieces were cut into a size of 1 cm×10 cm, and the fracture elongation was measured using the above method. The measurement results served as the fracture elongation after aging Ee.

### Evaluation on Weather Resistance

As the index for evaluating the weather resistance, the fracture elongation retention ratio (percent) was calculated based on the following relationship:

Fracture elongation retention ratio=(Ee/Es)×100. The calculation results were used to evaluate the weather resistance according to the following criteria.

### Evaluation Criteria

A: Fracture elongation retention ratio of 50 or more percent
B: Fracture elongation retention ratio of from 30 to less than 50 percent
C: Fracture elongation retention ratio of less than 30 percent

The results of weather resistance of Backsheets BS-1 to BS-4 of Examples 91 to 94 and Comparative Backsheets RBS1 to RBS2 for solar cell of Comparative Examples 26 to 27 are shown in Table 7.

TABLE 7

| | | Backsheet | Weather |
|---|---|---|---|
| Example | (Co)polymer | for solar cell | resistance |
| Example 91 | CP-5 | BS-1 | A |
| Example 92 | CP-15 | BS-2 | A |
| Example 93 | CP-25 | BS-3 | A |
| Example 94 | CP-35 | BS-4 | A |
| Comparative | RCP-3 | RBS-1 | B |
| Example 26 | | | |
| Comparative | RCP-8 | RBS-2 | C |
| Example 27 | | | |

Aspects of the present disclosure are, for example, as follows.

Aspect 1: A polymer contains a structural unit represented by the following Chemical Formula 1

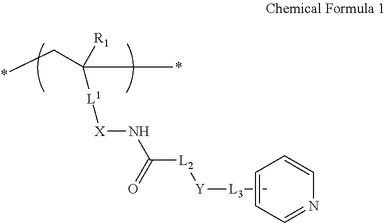

In Chemical formula 1, R₁ represents a hydrogen atom or a methyl group, L₁ represents —COO—, —CONH—, or a simple bonding, X represents a hydrocarbon group with 2 to 10 carbon atoms or a hydrocarbon group including an oxygen atom with 2 to 10 carbon atoms, L₂ represents —O— or —NH—, Y represents a hydrocarbon group with 2 to 12 carbon atoms or a simple bonding, and L₃ represents —OCO—, —O—, —(CH₂)ₙ—, or —OCO—(CH₂)ₙ—, where n represents an integer of from 1 to 3.

Aspect 2: A copolymer having the structural unit represented by the following Chemical Formula 1 and a structural unit represented by Chemical Formula 2.

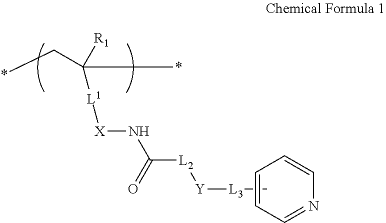

In Chemical formula 1, R₁ represents a hydrogen atom or a methyl group, L₁ represents —COO—, —CONH—, or a simple bonding, X represents a hydrocarbon group with 2 to 10 carbon atoms or a hydrocarbon group including an oxygen atom with 2 to 10 carbon atoms, L₂ represents —O— or —NH—, Y represents a hydrocarbon group with 2 to 12 carbon atoms or a simple bonding, and L₃ represents —OCO—, —O—, —(CH₂)ₙ—, or —OCO—(CH₂)ₙ—, where n represents an integer of from 1 to 3.

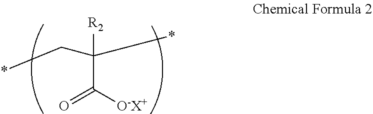

In Chemical Formula 2, R₂ represents a hydrogen atom or a methyl group and X⁺ represents a proton or an organic or inorganic cation.

Aspect 3: An ink contains a polymer with the structural unit represented by Chemical Formula 1 or a copolymer with the structural unit represented by Chemical Formula 1 and the structural unit represented by Chemical Formula 2.

Aspect 4: The ink according to Aspect 3 mentioned above, wherein the polymer or the copolymer has a weight average molecular weight of from 5,000 to 50,000.

Aspect 5: The ink according to Aspect 3 or 4 mentioned above, wherein the coloring material is a water-dispersible pigment.

Aspect 6: An ink container containing the ink of any one of Aspects 3 to 5 mentioned above.

Aspect 7: An image forming method includes discharging the ink of any one of Aspects 3 to 5 mentioned above to a printing medium to form an image thereon.

Aspect 8: An image forming device includes the ink container of Aspect 6 mentioned above and a discharging device for discharging the ink accommodated in the ink container to a printing medium.

Aspect 9: A backsheet for solar cell includes a protection sheet being a coated film formed of the ink of any one of Aspects 3 to 5 mentioned above.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention.

1. A polymer comprising:
a structural unit represented by the following Chemical Formula 1 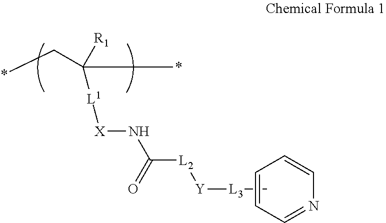
where R₁ represents a hydrogen atom or a methyl group, L₁ represents —COO—, —CONH—, or a simple bonding, X represents a hydrocarbon group with 2 to 10 carbon atoms or a hydrocarbon group including an oxygen atom with 2 to 10 carbon atoms, L₂ represents —O— or —NH—, Y represents a hydrocarbon group with 2 to 12 carbon atoms or a simple bonding, and L₃ represents —OCO—, —O—, —(CH₂)ₙ—, or —OCO—(CH₂)ₙ—, where n represents an integer of from 1 to 3.

2. A copolymer comprising:
a structural unit represented by the following Chemical Formula 1; and
a structural unit represented by Chemical Formula 2, 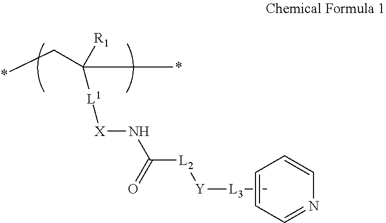
where R₁ represents a hydrogen atom or a methyl group, L₁ represents —COO—, —CONH—, or a simple bonding, X represents a hydrocarbon group with 2 to 10 carbon atoms or a hydrocarbon group including an oxygen atom with 2 to 10 carbon atoms, L₂ represents —O— or —NH—, Y represents a hydrocarbon group with 2 to 12 carbon atoms or a simple bonding, and L₃ represents —OCO—, —O—, —(CH₂)ₙ—, or —OCO—(CH₂)ₙ—, where n represents an integer of from 1 to 3, 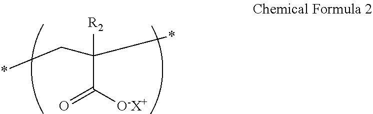
where R₂ represents a hydrogen atom or a methyl group and X⁺ represents a proton or an organic or inorganic cation.

3. An ink comprising:
water;
a coloring material; and
either a polymer or a copolymer,
the polymer comprising:
a structural unit represented by the following Chemical Formula 1, 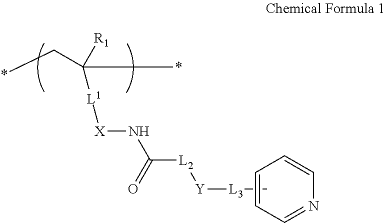
where R₁ represents a hydrogen atom or a methyl group, L₁ represents —COO—, —CONH—, or a simple bonding, X represents a hydrocarbon group with 2 to 10 carbon atoms or a hydrocarbon group including an oxygen atom with 2 to 10 carbon atoms, L₂ represents —O— or —NH—, Y represents a hydrocarbon group with 2 to 12 carbon atoms or a simple bonding, and L₃ represents —OCO—, —O—, —(CH₂)ₙ—, or —OCO—(CH₂)ₙ—, where n represents an integer of from 1 to 3,
the copolymer comprising:
a structural unit represented by Chemical Formula 1; and
a structural unit represented by Chemical Formula 2, 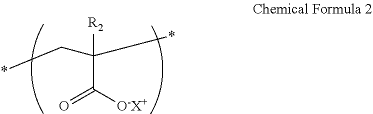
where R₂ represents a hydrogen atom or a methyl group and X⁺ represents a proton or an organic or inorganic cation.

4. The ink according to claim 3, wherein the polymer or the copolymer has a weight average molecular weight of from 5,000 to 50,000.

5. The ink according to claim 3, wherein the coloring material comprises titanium oxide.

6. An ink container containing the ink of claim 3.

7. An image forming method comprising:
discharging the ink of claim 3 to a printing medium to form an image thereon.

8. An image forming device comprising:
the ink container of claim 6; and
a discharging device to discharge the ink to a printing medium.

9. A backsheet for solar cell, comprising:
a protection layer comprising a coated film comprising the ink of claim 3.
